(19) United States
(12) Patent Application Publication
(10) Pub. No.: US 2016/0378684 A1
(43) Pub. Date: Dec. 29, 2016

(54) MULTI-PAGE CHECK HINTS FOR SELECTIVE CHECKING OF PROTECTED CONTAINER PAGE VERSUS REGULAR PAGE TYPE INDICATIONS FOR PAGES OF CONVERTIBLE MEMORY

(71) Applicant: INTEL CORPORATION, Santa Clara, CA (US)

(72) Inventors: KRYSTOF C. ZMUDZINSKI, Forest Grove, OR (US); VEDVYAS SHANBHOGUE, Austin, TX (US)

(73) Assignee: INTEL CORPORATION, Santa Clara, CA (US)

(21) Appl. No.: 14/751,902

(22) Filed: Jun. 26, 2015

(51) Int. Cl. G06F 12/10; G11C 7/10

(52) U.S. Cl. CPC G06F 12/1027; G06F 12/1009; G11C 7/1072; G06F 2212/651; G06F 2212/305; G06F 2212/684

(57) ABSTRACT

A processor of an aspect includes at least one translation lookaside buffer (TLB) and a memory management unit (MMU). Each TLB is to store translations of logical addresses to corresponding physical addresses. The MMU, in response to a miss in the at least one TLB for a translation of a first logical address to a corresponding physical address, is to check for a multi-page protected container page versus regular page (P/R) check hint. If the multi-page P/R check hint is found, then the MMU is to check a P/R indication. If the multi-page P/R check hint is not found, then the MMU does not check the P/R indication. Other processors, methods, and systems are also disclosed.

### BACKGROUND

Technical Field

Embodiments described herein generally relate to security. In particular, embodiments described herein generally relate to enclaves and other protected containers.

Background Information

Desktop computers, laptop computers, smartphones, servers, and various other types of computer systems are often used to process secret or confidential information. Examples of such secret or confidential information include, but are not limited to, passwords, account information, financial information, information during financial transactions, confidential company data, enterprise rights management information, personal calendars, personal contacts, medical information, other personal information, and the like. It is generally desirable to protect such secret or confidential information from inspection, tampering, theft, and the like.

### BRIEF DESCRIPTION OF THE DRAWINGS

The invention may best be understood by referring to the following description and accompanying drawings that are used to illustrate embodiments. In the drawings:

FIG. 1 is a block diagram of an embodiment of a computer system in which embodiments may be implemented.

FIG. 2 is a block flow diagram of an embodiment of a method of checking for and using a multi-page protected container page versus regular page (P/R) check hint in conjunction with performing a page table walk.

FIG. 3 is a block diagram of an example embodiment of hierarchical paging structures and showing suitable locations for multi-page P/R check hints.

FIG. 4 is a block flow diagram of an example embodiment of a more detailed method of checking for and using a multi-page P/R check hint in conjunction with performing a page table walk.

FIG. 5 is a block flow diagram of an embodiment of a method of providing multi-page P/R check hints to a processor.

FIG. 6 is a block diagram of an embodiment of a privileged system module to provide multi-page P/R check hints.

FIG. 7A is a block diagram illustrating an embodiment of an in-order pipeline and an embodiment of a register renaming out-of-order issue/execution pipeline.

FIG. 7B is a block diagram of an embodiment of processor core including a front end unit coupled to an execution engine unit and both coupled to a memory unit.

FIG. 8A is a block diagram of an embodiment of a single processor core, along with its connection to the on-die interconnect network, and with its local subset of the Level 2 (L2) cache.

FIG. 8B is a block diagram of an embodiment of an expanded view of part of the processor core of FIG. 8A.

FIG. 9 is a block diagram of an embodiment of a processor that may have more than one core, may have an integrated memory controller, and may have integrated graphics.

FIG. 10 is a block diagram of a first embodiment of a computer architecture.

FIG. 11 is a block diagram of a second embodiment of a computer architecture.

FIG. 12 is a block diagram of a third embodiment of a computer architecture.

FIG. 13 is a block diagram of a fourth embodiment of a computer architecture.

FIG. 14 is a block diagram of use of a software instruction converter to convert binary instructions in a source instruction set to binary instructions in a target instruction set, according to embodiments of the invention.

### 1. DETAILED DESCRIPTION OF EMBODIMENTS

Disclosed herein are multi-page check hints for selective checking of protected container page versus regular page type indications for pages of convertible memory. Also disclosed are processors to detect and use the multi-page check hints, methods in processors of detecting and using the multi-page check hints, methods and modules to provide the multi-page check hints, and systems in which the multi-page check hints may be used. In the following description, numerous specific details are set forth (e.g., specific instruction operations, data formats, processor configurations, microarchitectural details, sequences of operations, etc.). However, embodiments may be practiced without these specific details. In other instances, well-known circuits, structures and techniques have not been shown in detail to avoid obscuring the understanding of the description.

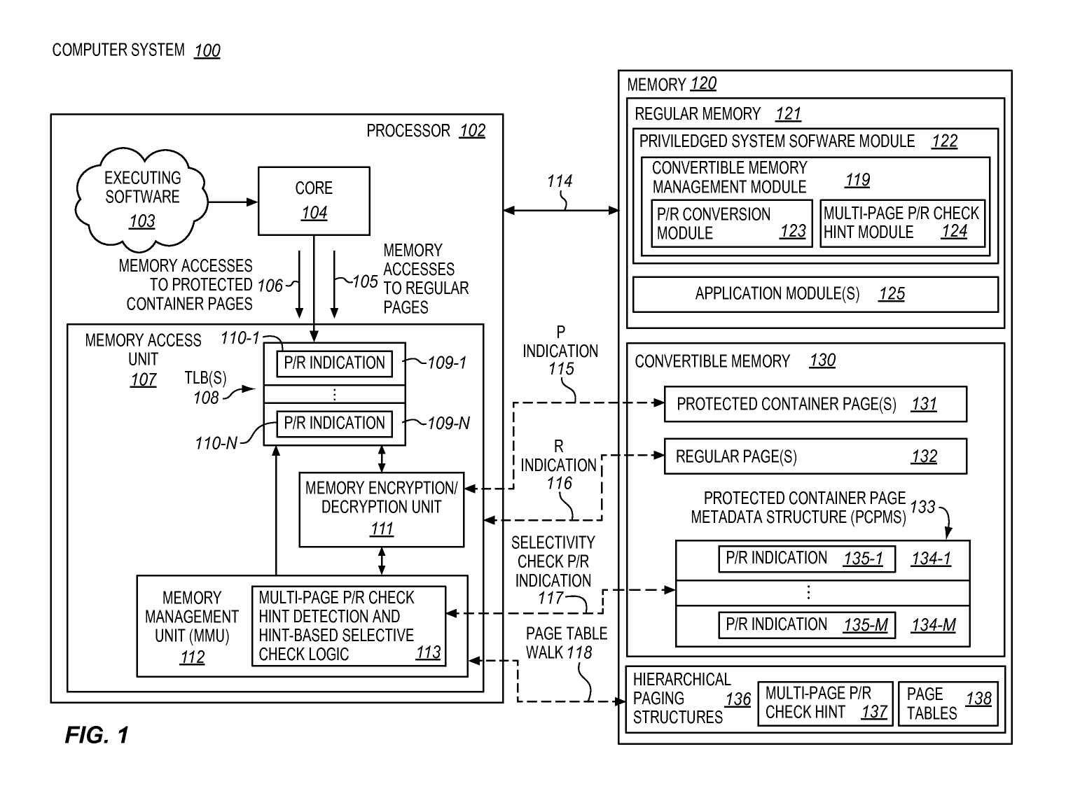

FIG. 1 is a block diagram of an embodiment of a computer system 100 in which embodiments may be implemented. The computer system includes at least one processor 102 and a memory 120. The memory may include one or more types of physical memory devices. The processor and the memory may be coupled with one another, or otherwise in communication with one another, by one or more coupling mechanisms 114. Examples of suitable coupling mechanisms include, but are not limited to, one or more buses or other interconnects, one or more chipset components, a combination thereof, and other mechanisms to couple a processor and memory.

In some embodiments, the memory includes both regular memory 121 and convertible memory 130. The regular memory may represent memory of the type commonly used to store applications and data. As shown, the regular memory may store a privileged-level system software module 122, such as, for example, an operating system module, a virtual machine monitor module, or the like. The regular memory may also store one or more user-level application modules 125, such as, for example, a word processing application, spreadsheet, email application, Internet browser, etc.

The convertible memory 130 may represent a type of memory in which portions thereof may be inter-converted between regular type memory and protected container type memory. For example, pages or other portions of the convertible memory may be converted from regular memory pages or portions to protected container pages or portions and/or from protected container pages or portions to regular memory pages or portions. As shown, the convertible memory may have one or more protected container pages 131 and one or more regular pages 132. The protected container pages may be more secured or protected than the regular pages. The protected container pages may be used to implement protected containers. Examples of suitable protected containers, according to various embodiments, include but are not limited to, secure enclaves, hardware managed isolated execution environments, hardware managed isolated execution regions, and the like. In some embodiments, the protected container pages 131 may represent pages of an Intel® Software Guard Extensions (Intel® SGX) secure enclave, and the convertible memory 130 may represent a flexible enclave page cache (EPC), although the scope of the invention is not so limited. In some embodiments, the convertible memory may be configured at boot time by a basic input/output system (BIOS), for example, by the BIOS configuring range registers of the processor.

Different types of security features may be used to protect the protected container pages 131 in different embodiments. In some embodiments, the processor may inherently, natively, and/or transparently to software, store code and/or data encrypted in the protected container pages 131 in the convertible memory, but the processor may not inherently, natively, and/or transparently to software (e.g., without needing to execute encryption instructions), store code and/or data encrypted in the regular pages 132 of the convertible memory. For example, in some embodiments, all writes to the protected container pages (e.g., due to cache evictions, etc.), and all reads from the protected container pages in the convertible memory, may be performed through a memory encryption and decryption unit 111, whereas reads from and writes to the regular pages in the convertible memory may bypass the memory encryption and decryption unit. In some embodiments, the processor may also inherently, natively, and/or transparently to software, perform integrity protection and/or replay protection on the protected container pages, but the processor may not inherently, natively, and/or transparently to software, perform integrity protection and/or replay protection on the regular pages of the convertible memory or pages in the regular memory 121.

In some embodiments, the processor and/or a memory access unit 107 may be operative to only allow accesses to the protected container pages 131 from code executing within a same protected container to which the protected container pages are allocated. Code, data, and stack inside the protected container may be protected from accesses by software, even higher-privilege level software (e.g., OS, VMM, BIOS, etc.), not resident in the protected container. In some embodiments, memory access control logic of the processor may also control or restrict unauthorized accesses to code and data of a protected container page while it is resident in registers, caches, and other on-die logic of the processor. Advantageously, secret or confidential information may be stored in the protected container while maintaining confidentiality and integrity of the data even in the presence of privileged malware.

Referring again to FIG. 1, the privileged system software module includes an embodiment of a convertible memory management module 119. The convertible memory management module may be operative to manage the convertible memory 130. The convertible memory management module may include a protected container page versus regular page (P/R) conversion module 123. The P/R conversion module may be operative to inter-convert pages of the convertible memory between regular and protected container pages. For example, the P/R conversion module may convert protected container pages to regular pages and/or convert regular pages to protected container pages. In some embodiments, the P/R conversion module may execute privileged-level page conversion instructions to convert pages of the convertible memory between regular and protected container pages. For example, in an embodiment of an Intel® SGX implementation of a flexible EPC, the module may have the processor perform an EMKEPC instruction to convert a page of the flexible EPC to an enclave page and/or an EMKREG instruction to convert a page of the flexible EPC to a regular page, although the scope of the invention is not so limited.

One potential advantage of the convertible memory 130 is that the pages thereof may be converted between regular and protected container pages to change the relative numbers and/or proportions thereof dynamically during runtime depending on need. Representatively, when more protected container pages are needed than regular pages, the P/R conversion module may convert a greater proportion of the pages in the convertible memory to be protected container pages as opposed to regular pages. Conversely, when more regular pages are needed than protected container pages, the P/R conversion module may convert a greater proportion of the pages in the convertible memory to be regular pages as opposed to protected container pages. This may help to avoid a potential underutilization of a statically fixed amount of memory for the protected container pages. Also, this may help to allow overall greater utilization of pages of memory, since relative proportions of protected container and regular pages may be dynamically reconfigured during runtime depending on need. As one possible example, servers in a datacenter may potentially use more protected container pages during certain times or workloads (e.g., during the daytime when more business transactions are being performed) and may use less protected container pages during other times or workloads (e.g., during the night when the servers are used more for steaming of movies and other content).

In some embodiments, a protected container page metadata structure (PCPMS) 133 may be used to store security and other metadata for each page in the convertible memory 130. One example of a suitable PCPMS is an Intel® SGX enclave page cache map (EPCM), although the scope of the invention is not so limited. Other PCPMS may have different structures and attributes than an EPCM. In some embodiments, the PCPMS may be stored in the convertible memory as a protected container page to provide security and/or protection. Accesses to data in the PCPMS, when it is stored in the memory, may tend to be relatively expensive due in part to relatively longer latency memory accesses. Alternatively, the PCPMS may optionally be stored elsewhere, such as, for example, in secure on-die storage space on the processor (e.g., portions of one or more caches, dedicated storage, etc.). In one aspect, the PCPMS may be structured to have different entries for different corresponding pages in the convertible memory, although other ways of structuring the PCPMS are also possible (e.g., other types of tables, data structures, etc.). For example, the PCPMS may have a first entry 134-1 corresponding to a first page, through an Mth entry 134-M corresponding to an Mth page. Each entry may store security and optionally other metadata for the corresponding page. Examples of suitable types of metadata for protected container pages include, but are not limited to, information to indicate whether the page is valid or invalid, information to indicate a protected container to which the protected container page belongs, information to indicate the virtual address through which the protected container page is allowed to be accessed, information to indicate read/write/execute permissions for the protected container page, and the like, and various combinations thereof, depending upon the particular implementation. The scope of the invention is not limited to any known type of security or other metadata to be stored in the PCPMS.

Referring again to FIG. 1, as shown, in some embodiments, the PCPMS may store a corresponding protected container versus regular (P/R) indication 135 for each page in the convertible memory. For example, as shown the first entry may have a first protected container versus regular (P/R) indication 135-1, through the Mth entry having an Mth P/R indication 135-M. Alternatively, the P/R indications may optionally be located elsewhere, such as, for example, storing protected indications within the protected container pages 131 and regular indications within the regular pages 132, in a structure on-die with the memory access unit 107, in an array of per-page P/R bits in protected on-die processor logic or sufficiently protected memory, etc. These P/R indications may be used to identify whether pages are protected container or regular type at page granularity. Each P/R indication may be operative to indicate whether the corresponding page in the convertible memory is currently configured as a protected container page or a regular page. One example of a suitable P/R indication, in an Intel® SGX implementation, is an EPCM.E bit in an EPCM, which may be set to binary one to indicate that the corresponding page is an enclave page or cleared to binary zero to indicate that the corresponding page is a regular page, although the scope of the invention is not so limited. In some embodiments, these EPCM.E bits or other P/R indications may be configured by the privileged system software module 122. For example, the convertible memory management module 119 and/or the P/R conversion module 123 may configure the P/R indications appropriately when pages in the convertible memory are converted between regular and protected container types. As one specific example, in an Intel® SGX implementation with flexible EPC, the EPCM.E bit may be set responsive to performing the EMKEPC instruction, and cleared responsive to performing the EMKREG instruction. The P/R indications 135 may be used in part to handle pages with appropriate security (e.g., to apply protected container security mechanisms to the protected container pages but not to the regular pages).

During operation, executing software 103 may execute on the processor 102. For example, the executing software may include instructions that may be provided to a core 104 of the processor. The core may include a decode unit to decode the instructions, an execution unit to execute the instructions, etc. The executing software may include software that attempts accesses 106 to the protected container pages 131, as well as software that attempts accesses 105 to the regular pages 132. These memory access attempts may be directed to the memory access unit 107.

Typically, the memory access attempts 105, 106 may be made with logical memory addresses (e.g., virtual or linear memory addresses). The logical memory addresses may need to be converted to corresponding physical memory addresses in order to identify the appropriate physical pages in the memory. The logical memory addresses may be provided to at least one translation lookaside buffer (TLB) 108. In one aspect, there may be a single TLB. In another aspect, there may be multiple TLBs (e.g., at different levels). The at least one TLB may cache or otherwise store previous logical to physical memory address translations. For example, after a page table walk has been performed to translate a logical address to a physical address, the address translation may be cached in the TLB. If the address translation is needed again, within a short enough period of time, then the address translation may be retrieved quickly from the TLB, instead of needing to more slowly repeat the page table walk. Typically, the TLB may have different entries to store different address translations. As shown, the TLB may have a first entry 109-1 through an Nth entry 109-N. In some embodiments, each entry may store a protected container versus regular (P/R) indication for a previously obtained corresponding translation. For example, the first entry may store a first P/R indication 110-1, through the Nth entry storing an Nth P/R indication 110-N. The P/R indications may indicate whether the corresponding page is a protected container page or a regular page. These P/R indications in the TLB(s) may be, but need not be, exact copies of the P/R indications 135 from the PCPMS, as long as they convey consistent P/R indications.

The appropriate address translation either will be stored in the one or more TLBs, or it will not. A TLB “hit” occurs when the appropriate address translation is stored in the one or more TLBs. Conversely, a TLB “miss” occurs when the appropriate address translation is not stored in the one or more TLBs. In the event of a TLB “hit” the address translation may be retrieved from the TLB entry, and used to access the page in the memory. In some embodiments, the corresponding P/R indication may also be retrieved from the TLB entry, and used during the access to control whether the page is accessed as a protected container page or a regular page. If the retrieved P/R indication indicates that the page is a regular page, then the regular page may be accessed without performing a set of security and/or protection operations which are used to access the protected container pages. For example, as shown by arrow 116, the memory access unit may access the regular page, bypassing the memory encryption and decryption unit, if the retrieved P/R indication is an R indication that indicates that the page is a regular page. Conversely, if the P/R indication is a P indication that indicates that the page is a protected container page, then the protected container page may be accessed with the set of security and/or protection operations intended to be used to access the protected container pages. For example, as shown by arrow 115, the access to the protected container page may be made through the memory encryption and decryption unit. Other protections described for the protected container may also be applied.

In the event of a TLB “miss,” the sought address translation is not stored in the one or more TLBs. Moreover, the P/R indication for the page being accessed is not stored in the one or more TLBs. Such TLB misses may be directed to a memory management unit (MMU) 112. The MMU may include a page miss handler unit or logic, a page table walk unit or logic, or the like. The MMU may be implemented in hardware (e.g., integrated circuitry, transistors or other circuit elements, etc.), firmware (e.g., ROM, EPROM, flash memory, or other persistent or non-volatile memory and microcode, microinstructions, or other lower-level instructions stored therein), software (e.g., higher-level instructions stored in memory), or a combination thereof (e.g., hardware and/or firmware potentially combined with some software).

The MMU unit 112 (e.g., a page miss handler subunit thereof) may be operative to perform a page table walk to determine the logical (e.g., virtual or linear) to physical address translation. The MMU and/or a page miss handler unit thereof may access a set of hierarchical paging structures 136. In some embodiments, the hierarchical paging structures may be stored in the regular memory, or in other embodiments in the convertible memory. Different hierarchical paging structures are suitable for different embodiments. The MMU may be operative to “walk” or advance through the hierarchical paging structures until ultimately reaching paging tables 138, which may have page table entries that store physical addresses of corresponding pages. The physical addresses may be used to access the pages from the memory. The determined address translation may also be stored in an entry in the one or more TLBs for possible future use.

Now, in addition to the determined address translation, in some embodiments, the processor may also need to know whether the page being accessed is a protected container page or a regular page, at least when the page being accessed is in the convertible memory, so that the page may be accessed with appropriate security. One possible approach would be for the processor (e.g., the MMU) to access the P/R indications 135 in the PCPMS for each page accessed following a TLB miss. However, such accesses to the P/R indications in the PCPMS may tend to reduce performance. For one thing, in embodiments where the PCPMS is in memory, such accesses to the P/R indications generally tend to be have relatively long memory access latencies. Moreover, even if the PCPMS were not stored in memory (e.g., was on-die of the processor), such accesses would still generally need to be performed with an additional operation that is not already part of the page table walk set of operations. Thus, additional overhead and an associated performance penalty may be incurred due to checking the P/R indications in the PCPMS (or even if they are stored elsewhere). This may be true even when very little software, or even no software, is using the protected container pages. Eliminating at least some of such checking of the P/R indications in the PCPMS may help to increase performance.

Referring again to FIG. 1, in some embodiments, the convertible memory management module 119 may include an embodiment of a multi-page protected container page versus regular page (P/R) check hint module 124. Alternatively, the P/R check hint module may be part of the privileged system software module 122, but not necessarily part of the convertible memory management module. The P/R check hint module may be operative to store or otherwise provide a multi-page P/R check hint 137 to the processor. In some embodiments, the multi-page P/R check hint may hint or indicate to the processor that the P/R indications 135 in the PCPMS (or even if they are stored elsewhere in other embodiments) should be checked in order to determine whether pages being accessed, within the scope of the multiple pages of the P/R check hint, are protected container pages or regular pages.

As its name implies, in some embodiments, the multi-page P/R check hint 137 may apply or pertain to multiple pages, as opposed to just a single page. As shown, in some embodiments, the P/R check hint module 124 may be operable to store the multi-page P/R check hint in the hierarchical paging structures 136. As further shown, in some embodiments, the multi-page P/R check hint may be stored outside of the page tables 138 (i.e., outside of the page table entries thereof). Another possible approach would be to store a single page P/R check hint in a bit of a page table entry in the page tables. In such an approach, the single page P/R check hint would apply only to that single page. However, the number of bits in page table entries generally tend to be limited. In some implementations, there may not be an additional available bit in the page table entries (e.g., they may all be already being used by system software for other purposes). In other implementations, there may be one or more additional available bits in the page table entries, but it may be desired to use or reserve them for other purposes. For example, it may be desired to reserve these additional bit(s) in the page table entries so that they may instead be used in the future to extend the physical address space.

As shown, in some embodiments, the MMU may include a multi-page P/R check hint detection and hint-based selective check logic 113 that is operable to detect the multi-page P/R check hint 137 (when one is stored or otherwise provided) for example while the MMU 112 is performing a page table walk 118 and selectively check 117 P/R indications 135 in the PCPMS based on whether the multi-page P/R check hint has been detected. Alternatively, the logic 113 may optionally be located outside of the MMU (e.g., in the memory access unit and/or in the processor). In some embodiments, the processor and/or the MMU may be operative to check for a multi-page P/R check hint. For example, the processor and/or the MMU may check for the multi-page P/R check hint at the time of (e.g., right before starting and/or during and/or immediately after) a page table walk and/or in conjunction with performing a page table walk. In some embodiments, if the multi-page P/R check hint is found, then the processor and/or the MMU may be operative to selectively check a corresponding P/R indication in the PCPMS. In some embodiments, if the multi-page P/R check hint is not found, then the processor and/or the MMU may be operative to selectively not check the corresponding P/R indication in the PCPMS. Accordingly, the multi-page P/R check hint may allow the processor and/or the MMU to selectively access and check or not access and check the P/R indications depending upon whether or not a multi-page P/R hint with the sought page in its scope or domain (e.g., a memory range) has been detected. Advantageously, this may help to eliminate at least some of the checks of the P/R indications, which may help to improve performance.

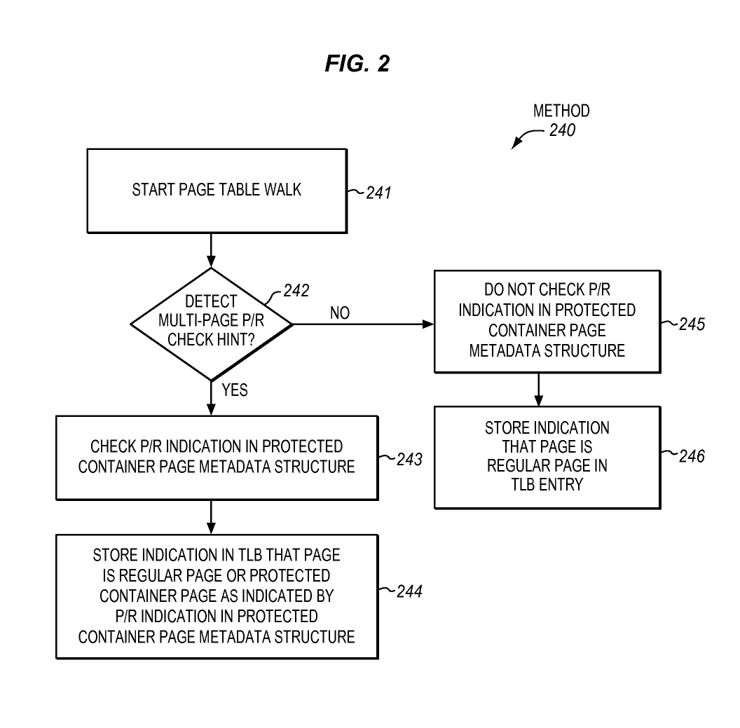

FIG. 2 is a block flow diagram of an embodiment of a method 240 of checking for and using a multi-page P/R check hint in conjunction with performing a page table walk. In various embodiments, the method may be performed by a processor, instruction processing apparatus, or other digital logic device. In some embodiments, the method 240 may be performed by and/or within the processor 102 of FIG. 1. The components, features, and specific optional details described herein for the processor 102, also optionally apply to the method 240. Alternatively, the method 240 may be performed by and/or within a similar or different processor or apparatus. Moreover, the processor 102 may perform methods similar to or different than the method 240.

The method includes starting a page table walk, at block 241. In some embodiments, an MMU and/or a page miss handler (PMH) unit may start the page table walk in response to a miss in at least one TLB for a translation of a given logical address to a corresponding physical address.

At block 242, the processor and/or the MMU and/or the PMH unit may check for and determine whether or not a multi-page P/R check hint is detected during the page table walk. In some embodiments, this may include checking one or more hierarchical paging structures, which are traversed during the page table walk, for the P/R check hint. For example, this may include checking in succession a page directory base register (PDBR), for example a CR3 register in certain Intel® Architecture compatible processors, and then checking one or more hierarchical paging structures at a hierarchical level between the page directory base register and a page table. For example, this may include checking in succession a directory or map of page directory pointer tables, and then a page directory pointer table, and then a page directory table. In other embodiments, there may be fewer or more hierarchical paging structures used during the page table walk, and correspondingly fewer or more hierarchical paging structures checked for the P/R check hint. Moreover, in some embodiments, one or more additional structures or storage locations may optionally be checked in conjunction with the page table walk (e.g., before beginning the page table walk, during the page table walk, after the page table walk). For example, in some embodiments, a core control register and/or a state save storage location may optionally be checked.

If a multi-page P/R check hint is found or detected at any level or point during the page table walk (i.e., “yes” is the determination at block 242), the method may advance to block 243. The P/R check hint may represent a hint (e.g., provided by privileged system software) to the processor that the P/R indication should be checked. At block 243, the processor and/or the MMU and/or the PMH unit may check a P/R indication. In some embodiments, the P/R indication may be stored in a PCPMS, which may be stored in memory. Thus, checking the P/R indication may include accessing the PCPMS in the memory. By way of example, in an Intel® SGX implementation embodiment, checking the P/R indication may include checking an EPCM.E bit in an EPCM, which may be set to binary one to indicate that the corresponding page is an enclave page or cleared to binary zero to indicate that the corresponding page is a regular page, although the scope of the invention is not so limited.

Then, at block 244, an indication may be stored in an entry of a TLB (e.g., which may be used to store a logical-to-physical address translation determined during the page table walk) that the page is either a regular page or a protected container page, as indicated by and consistent with the checked P/R indication (e.g., that was checked at block 243). By way of example, in an Intel® SGX implementation embodiment, if the EPCM.E bit in the EPCM is set to binary one, then the TLB entry may indicate that the page is an EPC page, or if the EPCM.E bit is cleared to binary zero, then the TLB entry may indicate that the page is a regular page, although the scope of the invention is not so limited.

Conversely, if a multi-page P/R check hint is not found or detected during the entire page table walk (i.e., “no” is the determination at block 242), the method may advance to block 245. At block 245, the processor and/or the MMU and/or the PMH unit may omit checking, or may not check, the P/R indication. In some embodiments, the P/R indication may be stored in the PCPMS, which may be stored in memory. Advantageously, omitting checking the P/R indication may avoid needing to access the PCPMS in memory, which may help to improve performance.

Then, at block 246, an indication that the page is a regular page (i.e., as opposed to a protected container page) may be stored in a TLB entry. The TLB entry may also be used to store a logical-to-physical address translation determined during the page table walk.

Accordingly, the multi-page P/R check hint may allow the processor and/or the MMU and/or the PMH unit to selectively check or not check the P/R indications depending upon whether or not a multi-page P/R check hint, with the sought page in its range, scope, or domain, is detected. Advantageously, this may help to eliminate at least some of the checks of the P/R indications, which especially when they are stored in memory may tend to be costly to check, which in turn may help to improve performance. For example, if software (e.g., a process) does not use protected container pages, the overhead otherwise needed to check the P/R indications may be substantially eliminated when the multi-page P/R check hint is included at any of various locations in the hierarchical paging structures. Or, for software that uses some protected container pages, the overhead may be reduced significantly by including the multi-page P/R check hint in a hierarchical paging structure below the page directory base register (e.g., a page directory pointer table, a page directory table, etc.).

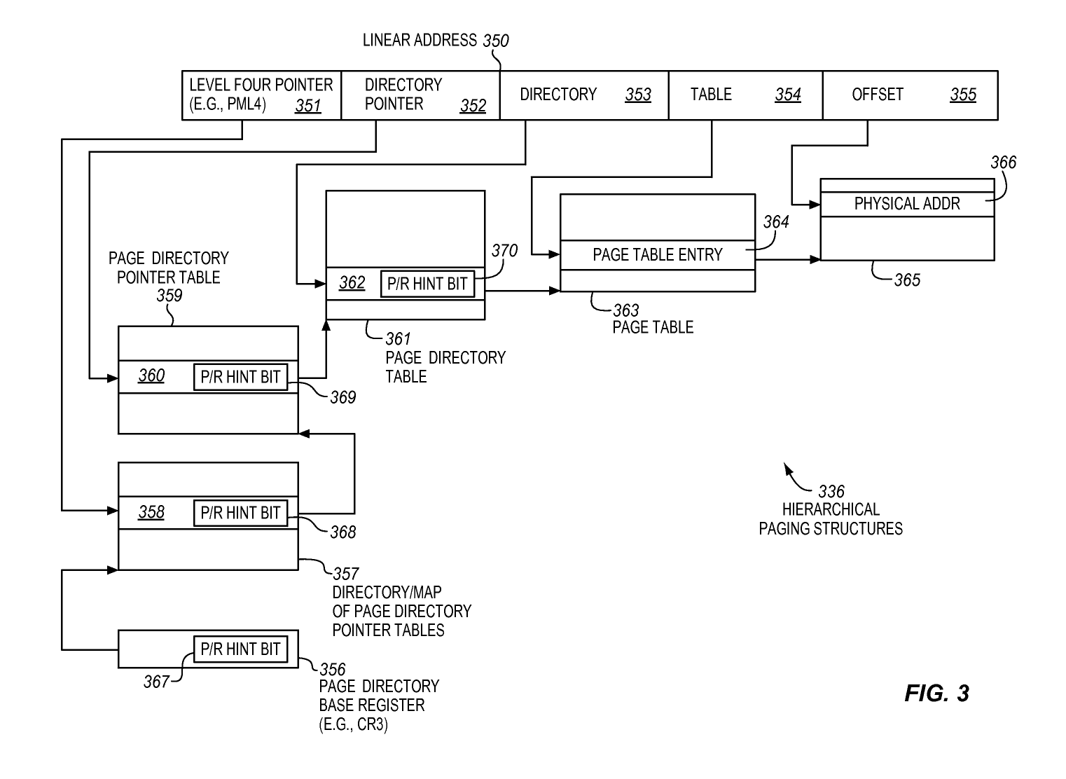

FIG. 3 is a block diagram of an example embodiment of a logical address 350 and a set of hierarchical paging structures 336 that may be used to identify physical pages 365 in memory. A page directory base register (PDBR) 356 may be used to store a base physical address of a highest level hierarchical paging structure. One example of a PDBR is a CR3 register in certain Intel® Architecture compatible processors. The PDBR may represent a processor register. Alternatively, instead of using a processor register, a data structure in memory may optionally have a field to store the page directory base.

In the illustrated example embodiment, a four level set of hierarchical paging structures is shown, although other embodiments may optionally have either fewer or more hierarchical levels. For example, one alternate implementation may have only a PDBR, a page directory, and page tables. Another alternate implementation may have only a PDBR, a page directory pointer table, a page directory, and page tables. Each of the hierarchical paging structures may represent a data structure in memory that is managed by privileged system software.

The highest level hierarchical paging structure in the illustration is a directory (or map) of page directory pointer tables 357. One suitable example is a page map level 4 (PML4) in certain Intel® Architecture compatible processors. The logical address in the illustrated example embodiment is a linear address. The linear address includes a level four pointer (e.g., a PML4) field 351. A pointer or value in the level four pointer field may be used to identify or select an entry 358 in the directory (or map) of page directory pointer tables. The entry 358 may contain the physical address of the base of a page directory pointer table 359 at a next level of the hierarchy. The 358 entry may also optionally include access rights and/or memory management information.

The linear address includes a directory pointer field 352. A pointer in the directory pointer field may be used to identify or select an entry 360 in the page directory pointer table. The entry 360 may contain the physical address of the base of a page directory table 361 at a next level of the hierarchy. The entry 360 may also optionally include access rights and/or memory management information. The linear address includes a directory field 353. A value in the directory field may be used to identify or select an entry 362 in the page directory table. The entry 362 may contain the physical address of the base of a page table 363 at a next level of the hierarchy. The entry 362 may also optionally include access rights and/or memory management information. The linear address includes a table field 354. The table field may be used to identify or select a page table entry 364 in the page table. The page table entry may contain the physical address of the base of a page frame in memory. The page table entry may also optionally include access rights and/or memory management information. The linear address also includes an offset field 355. The offset field may be used to identify or select a physical address of a physical page in memory.

In various embodiments, a multi-page P/R check hint may be stored or provided at any one or more of various different locations in the illustrated structures. As shown, in some embodiments, a multi-page P/R check hint 367 (e.g., a P/R hint bit) may optionally be stored in the PDBR. As further shown, in some embodiments, a multi-page P/R check hint 368 (e.g., a P/R hint bit) may optionally be stored in the entry in the directory (or map) of page directory pointer tables. As also shown, in some embodiments, a multi-page P/R check hint 369 (e.g., a P/R hint bit) may optionally be stored in the entry in the page directory pointer table. As further shown, in some embodiments, a multi-page P/R check hint 370 (e.g., a P/R hint bit) may optionally be stored in the entry in the page directory table. In various embodiments, a multi-page P/R check hint may optionally be stored at any one or more, or any combination, of these different locations or structures.

When the multi-page P/R check hint is stored or provided in the PDBR, it may indicate that the corresponding process uses protected container pages. In some embodiments, when the multi-page P/R check hint is stored in the CR3 register or other PDBR, it may indicate that the multi-page P/R check hint applies to an entire linear or logical address space of the corresponding process. In contrast, when the multi-page P/R check hint is stored or provided in an entry of one of the hierarchical paging structures at a hierarchical level between the PDBR and a page table, it may indicate that the multi-page P/R check hint applies to a linear or logical address range which is to be a subset of an entire logical address range of a process associated with the PDBR.

Detection of the multi-page P/R check hint in a given hierarchical paging structure may indicate that the corresponding process uses protected container pages and that there may potentially be protected container pages hierarchically below the location of the multi-page P/R check hint in the given hierarchical paging structure. For example, detection of the multi-page P/R check hint in a given entry in a given page directory table may indicate that the corresponding process uses protected container pages and that there may potentially be protected container pages mapped to any of the entries in a page table indicated by the given entry in the given page directory table. In other words, detection of a multi-page P/R check hint at a given hierarchical level may indicate that there may potentially be protected container pages mapped beneath that given hierarchical level. In various aspects, a process may have zero protected containers, one protected container, or multiple protected containers in its linear address space. In one aspect, each protected container may have its own corresponding P/R check hint. For example, correspondingly, there may be zero P/R check hints, one P/R check hint, or multiple P/R check hints. Representatively, each P/R check hint may be stored below the corresponding linear address space of the protected container.

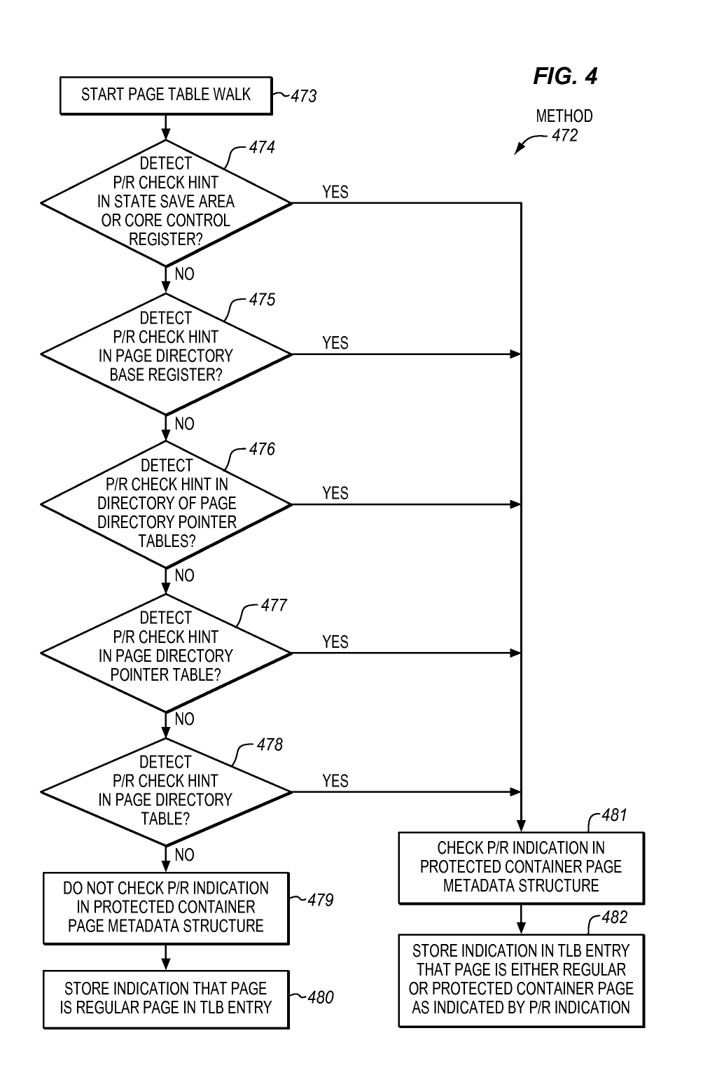

FIG. 4 is a block flow diagram of an example embodiment of a method 472 of checking for and using a multi-page P/R check hint in conjunction with performing a page table walk. In various embodiments, the method may be performed by a processor and/or an MMU and/or a PMH unit. In some embodiments, the method 472 may be performed by and/or within the processor 102 of FIG. 1. The components, features, and specific optional details described herein for the processor 102, also optionally apply to the method 472. Alternatively, the method 472 may be performed by and/or within a similar or different processor or apparatus. Moreover, the processor 102 may perform methods similar to or different than the method 472. In some embodiments, the method 472 may optionally be performed with the hierarchical paging structures of FIG. 3. Alternatively, the method may optionally be performed with similar or different hierarchical paging structures.

A page table walk may be started, at block 473. In some embodiments, the page table walk may be started in response to a miss in at least one TLB for a translation of a given logical address to a corresponding physical address.

At block 474, a determination may be made whether or not a multi-page P/R check hint is detected in either one of a state save area (e.g., an XSAVE area) and/or a core control register. In some embodiments, a multi-page P/R check hint detected in either the state save area and/or the core control register may apply to an entire linear address space of the corresponding process. If the multi-page P/R check hint is detected (i.e., if “yes” is the determination), the method may advance to block 481. Otherwise (i.e., if “no” is the determination), the method may advance to block 475.

At block 475, a determination may be made whether or not a multi-page P/R check hint is detected in a page directory base register (PDBR). In some embodiments, a multi-page P/R check hint detected in the PDBR (e.g., a CR3 register in certain Intel® Architecture compatible processors) may apply to an entire linear address space of the corresponding process associated with the given logical address. If the multi-page P/R check hint is detected (i.e., if “yes” is the determination), the method may advance to block 481. Otherwise (i.e., if “no” is the determination), the method may advance to block 476.

At block 476, a determination may be made whether or not a multi-page P/R check hint is detected in an entry of a directory (or map) of page directory pointer tables indicated by the PDBR and a first portion of the logical address. For example, this may include checking for the multi-page P/R check hint in an indicated entry of a PML4 table in certain Intel® Architecture compatible processors. If the multi-page P/R check hint is detected (i.e., if “yes” is the determination), the method may advance to block 481. Otherwise (i.e., if “no” is the determination), the method may advance to block 477.

At block 477, a determination may be made whether or not a multi-page P/R check hint is detected in an entry of a page directory pointer table indicated by the entry of the directory of page directory pointer tables and a second portion of the logical address. If the multi-page P/R check hint is detected (i.e., if “yes” is the determination), the method may advance to block 481. Otherwise (i.e., if “no” is the determination), the method may advance to block 478.

At block 478, a determination may be made whether or not a multi-page P/R check hint is detected in an entry in a page directory table indicated by the entry in the page directory pointer table and a third portion of the logical address. If the multi-page P/R check hint is detected (i.e., if “yes” is the determination), the method may advance to block 481. Otherwise (i.e., if “no” is the determination), the method may advance to block 479. Blocks 474-478 effectively represent checking different hierarchical paging structures as the page table walk works its way through these hierarchical paging structures.

The method may advance to block 481 if a multi-page P/R check hint is detected during any of the detections (e.g., if “yes” is the determination at any of blocks 474, 475, 476, 477, or 478). At block 481, the P/R indication may be checked. In some embodiments, the P/R indication may be stored in the protected container page metadata structure (PCPMS), which in some embodiments may be stored in memory. Then, at block 482, an indication may be stored in a TLB entry (e.g., one used to store a determined logical-to-physical address translation) that the page is either a protected container page or a regular page as indicated by and consistent with the checked P/R indication.

Alternatively, the method may advance to block 479 if a multi-page P/R check hint is not detected during any of the detections (e.g., if “no” is the determination at each of blocks 474-478). At block 479, the checking of the P/R indication may be omitted or not performed. In some embodiments, this may include omitting accessing and checking a PCPMS in memory. Then, at block 480, an indication may be stored in a TLB entry (e.g., one used to store a determined logical-to-physical address translation) that the page is a regular page.

This is just one illustrate example embodiment of a method. In other embodiments, fewer or more places or just different places may be checked for a multi-page P/R check hint.

For example, in one alternate embodiment, it may not be desired to use bits in any of the hierarchical paging structures of blocks 476-478. For example, there either may not be any available bits or it may be desired to reserve or use these bits for another purpose. In such cases, the multi-page P/R indication may instead optionally be stored (when appropriate) at either the PDBR, the state save area, the core control registers, or some combination thereof. Privileged system software may store the multi-page P/R indication in one of such places even if there was only one protected container page in the entire linear address space of the corresponding process. This may allow the privileged system software to indicate whether any part of the application or process uses protected container pages or not. On the one hand, such a multi-page P/R hint that applies to an entire linear address space of a process or application may tend to be less efficient if the process has a large number of memory accesses but a small proportion of which are really for protected container pages. On the other hand, any applications or processes that do not use any protected container pages at all may omit needing to check P/R indications, which may help to improve performance of these applications or processes.

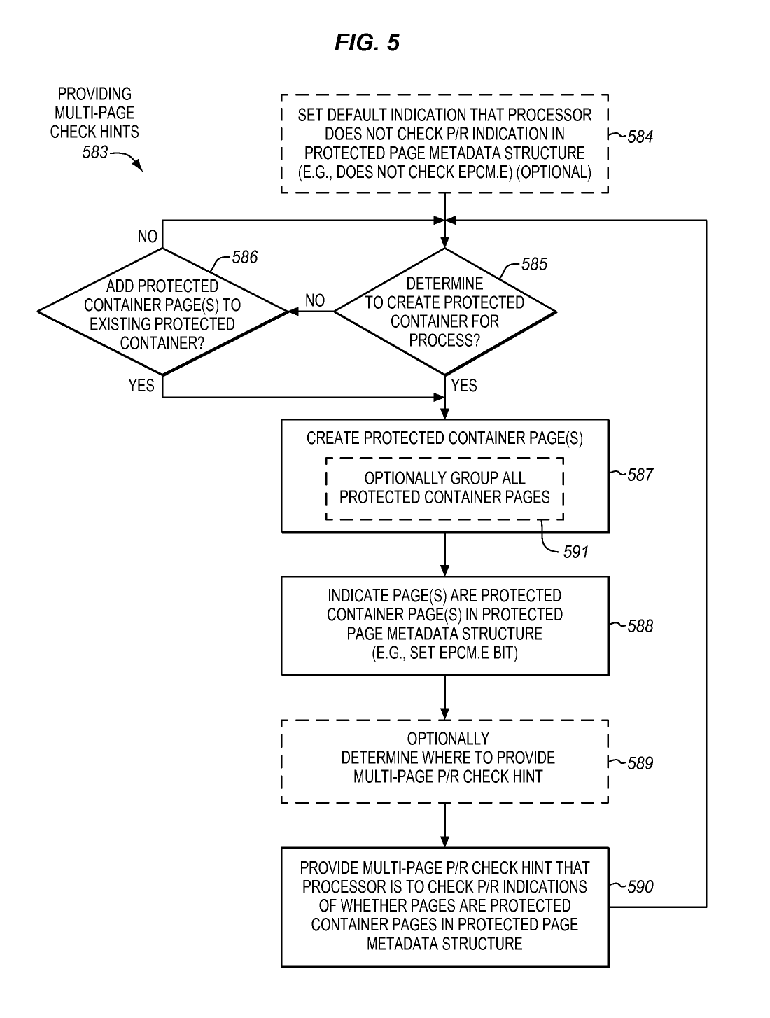

FIG. 5 is a block flow diagram of an embodiment of a method 583 of providing multi-page P/R check hints to a processor. In some embodiments, the method may be performed by privileged system software, such as, for example, an operating system, a virtual machine monitor, a hypervisor, or the like. In some embodiments, the method 583 may be performed by and/or within the computer system 100 of FIG. 1. The components, features, and specific optional details described herein for the computer system 100, also optionally apply to the method 583. Alternatively, the method 583 may be performed by and/or within a similar or different system. Moreover, the computer system 100 may perform methods similar to or different than the method 583.

The method may optionally include setting or configuring a default indication that the processor does not check P/R indications, for example in a protected container page metadata structure (PCPMS) in memory, at block 584. This is optional not required.

At block 585, a determination may be made whether or not a protected container is to be created for a processor or application. If a protected container is to be created for the processor or application (i.e., “yes” is the determination), the method may advance to block 587. Alternatively, if a protected container is not to be created for the processor or application (i.e., “no” is the determination), the method may advance to block 586.

At block 586, a determination may be made whether or not one or more protected container pages are to be added to an existing protected container. Protected container pages may potentially be created lazily so this may allow the privileged system software to update P/R indications over time as protected container pages are being added. If one or more protected container pages are to be added, (i.e., “yes” is the determination), the method may advance to block 587. Alternatively, if no protected container pages are to be added (i.e., “no” is the determination), the method may return to block 585.

At block 587, one or more protected container pages may be created. In some embodiments, this may include converting one or more regular pages of a convertible memory to the one or more protected container pages. By way of example, in an Intel® SGX implementation embodiment, this may include executing one or more EMKEPC instructions. In some embodiments, as shown at block 591, the one or more created protected container pages may optionally be grouped together and optionally grouped with other existing protected container pages (if any). In some embodiments, such grouping of the protected container pages may include grouping the protected container pages so that all of the protected container pages are hierarchically below and/or mapped to a given entry in a hierarchical paging structure (e.g., a given entry in one of a page directory/map of page directory pointer tables, a page directory pointer table, and a page directory table).

At block 588, the created protected container pages may be indicated to be protected container pages. For example, in some embodiments, an indication may be stored in a PCPMS in memory that the created pages are protected container pages. By way of example, in an Intel® SGX implementation embodiment, this may include setting EPCM.E bits for each of the created protected container pages in an EPCM (e.g., when executing EMKEPC instructions).

At block 589, an optional determination may be made of where to provide the multi-page P/R check hint, although this is not required. In some embodiments, this may include selecting one of multiple different possible locations to provide the multi-page P/R check hint. In some embodiments, this may include taking into consideration the performance expected if the multi-page P/R check hint is provided in each of the multiple different possible locations. In some embodiments, this may include determining to provide the multi-page P/R check hint at a lowest hierarchical level such that all protected container pages are hierarchically below and/or mapped to the determined lowest hierarchical level. In some embodiments, the determined location may at least encompass or cover the entire linear address space of the protected container pages. Alternatively, in other embodiments, a single fixed location may optionally be used to provide the multi-page P/R check hint.

At block 590, the multi-page P/R check hint may be stored or otherwise provided. In some embodiments, the multi-page P/R check hint may serve as a hint or indication to a processor that P/R indications of whether pages are protected container pages or regular pages are to be checked. In some embodiments, the P/R indications may be stored in a PCPMS in memory. In some embodiments, the multi-page P/R check hints may be provided outside of page table entries. This may have a potential advantage that the privileged system software doesn't have to modify every page table entry, but rather may place one multi-page P/R check hint that applies to multiple pages (e.g., on a per-process basis, a multi-page paging structure entry basis, etc.).

As shown, in some embodiments, the method may then revisit block 585. This may allow the privileged system software to potentially update the multi-page P/R check hint(s) (e.g., update their location(s)) during runtime depending on whether or not it is determined to add more pages to the protected container (e.g., at block 586). Moreover, the method may also optionally update the multi-page P/R check hint(s) when protected container pages are removed.

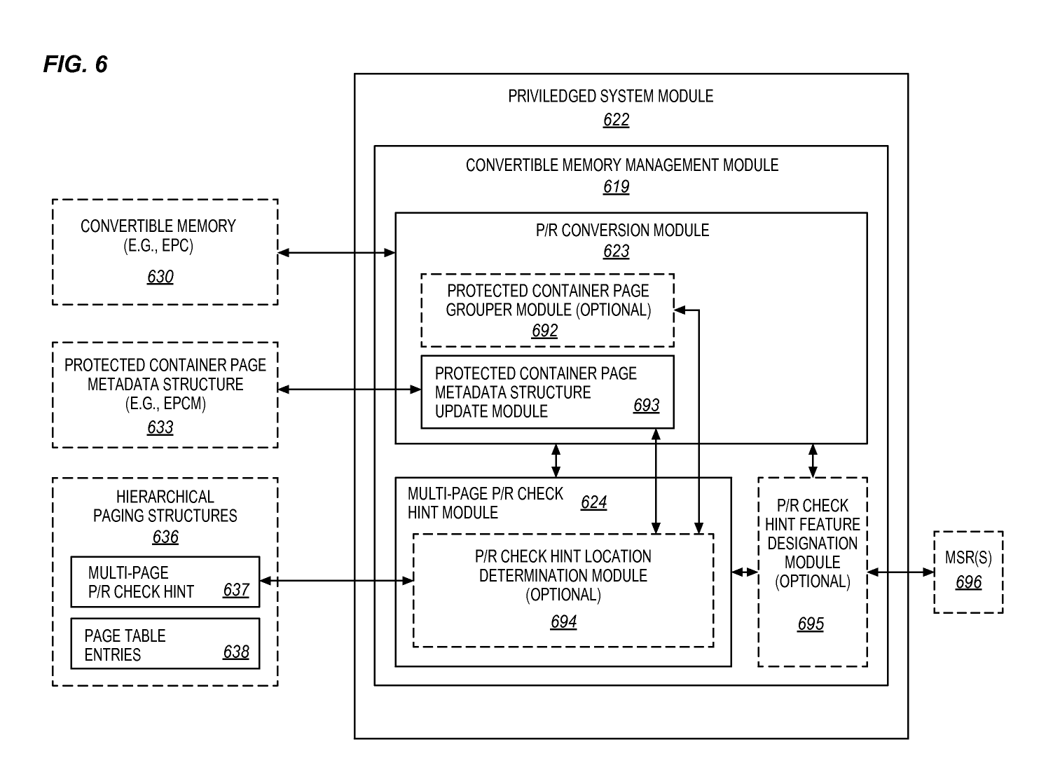

FIG. 6 is a block diagram of an embodiment of a privileged system module 622. In some embodiments, the privileged system module may be implemented in software, firmware, hardware, or a combination thereof (e.g., software with potentially some firmware).

The privileged system module includes a convertible memory management module 619. The convertible memory management module may be coupled with, or otherwise in communication with, a convertible memory 630. The convertible memory management module may be operative to manage the convertible memory. By way of example, in an Intel® SGX implementation embodiment, the convertible memory may represent a flexible enclave page cache (EPC), although the scope of the invention is not so limited.

The convertible memory management module includes a protected container page versus regular page (P/R) conversion module 623. The P/R conversion module may be operative to inter-convert pages of the convertible memory between regular and protected container pages. For example, the P/R conversion module may convert protected container pages to regular pages and/or convert regular pages to protected container pages. In some embodiments, the P/R conversion module may execute privileged-level page conversion instructions to convert pages of the convertible memory between regular and protected container pages. For example, in an embodiment of an Intel® SGX implementation, the module may have the processor perform an EMKEPC instruction to convert a page of a flexible EPC to an enclave page and/or an EMKREG instruction to convert a page of the flexible EPC to a regular page, although the scope of the invention is not so limited.

In some embodiments, the P/R conversion module may optionally include an optional protected container page grouper module 692, although this is not required. The protected container page grouper module may be operative to group protected container pages together within the convertible memory instead of having the protected container pages dispersed or spread out throughout the entire range of the convertible memory. In some embodiments, the protected container page grouper module may be operative to group all protected container pages together. In some embodiments, the protected container page grouper module may be operative to group all protected container pages, or at least sets of protected container pages, so that all of the protected container pages, or at least the sets of the protected container pages, are hierarchically beneath and/or mapped to a given entry in a hierarchical paging structure (e.g., a given entry in one of a page directory/map of page directory pointer tables, a page directory pointer table, and a page directory table). It is not required to group all protected container pages together. Rather, different groups of protected container pages may optionally be grouped together, for example, with each group hierarchically beneath and/or mapped to a given entry in a hierarchical paging structure.

In some embodiments, the P/R conversion module may include a protected container page metadata structure (PCPMS) update module 693. The PCPMS update module may be coupled with, or otherwise in communication with, a PCPMS 633. The PCPMS update module may be operative to update P/R indications in PCPMS. For example, in an embodiment of an Intel® SGX implementation, the update module may update EPCM.E bits in an EPCM as pages are inter-converted between regular and EPC pages.

The convertible memory management module also includes a multi-page P/R check hint module 624. The multi-page P/R check hint module may be coupled with, or otherwise in communication with, the P/R conversion module 623 and a set of hierarchical paging structures 636. In some embodiments, the multi-page P/R check hint module may be operative to provide a multi-page P/R hint in the hierarchical paging structures outside of page table entries 638. Alternatively, the multi-page P/R check hint module may be operative to provide the multi-page P/R hint in any of the other locations disclosed herein or other locations which have a scope of multiple pages and are outside of the page table entries. In some embodiments, the multi-page P/R check hint may provide a hint, suggestion, or indication to a processor that the processor is to check P/R indications for multiple pages. In some embodiments, the multi-page P/R check hint module may optionally include an optional P/R check hint location determination module that is operative to determine a location of a plurality of different possible locations to provide the multi-page P/R check hint which encompasses all protected container pages but not all regular pages. The location may be determined as described elsewhere herein.

In some embodiments, the convertible memory management module may optionally include an optional P/R check hint feature designation module 695. The feature designation module may be coupled with, or otherwise in communication with, the multi-page P/R check hint module and one or more registers of the processor 696 (e.g., one or more model specific registers (MSRs)). In some embodiments, the feature designation module may be operative to store an indication of one or more locations where one or more multi-page P/R check hints are to be provided in the one or more registers of the processor 696. For example, the feature designation module may specify or indicate whether the privileged system module is going to use a PDBR, a state save area, a core control register, a hierarchical paging structure, or some combination thereof to store the multi-page P/R check hints. In one aspect, this may inform the processor where to check so that the processor may selectively check in the indicated locations for efficiency and/or additional security.

Exemplary Core Architectures, Processors, and Computer Architectures

Processor cores may be implemented in different ways, for different purposes, and in different processors. For instance, implementations of such cores may include: 1) a general purpose in-order core intended for general-purpose computing; 2) a high performance general purpose out-of-order core intended for general-purpose computing; 3) a special purpose core intended primarily for graphics and/or scientific (throughput) computing. Implementations of different processors may include: 1) a CPU including one or more general purpose in-order cores intended for general-purpose computing and/or one or more general purpose out-of-order cores intended for general-purpose computing; and 2) a coprocessor including one or more special purpose cores intended primarily for graphics and/or scientific (throughput). Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip that may include on the same die the described CPU (sometimes referred to as the application core(s) or application processor(s)), the above described coprocessor, and additional functionality. Exemplary core architectures are described next, followed by descriptions of exemplary processors and computer architectures.

Exemplary Core Architectures

In-Order and Out-of-Order Core Block Diagram

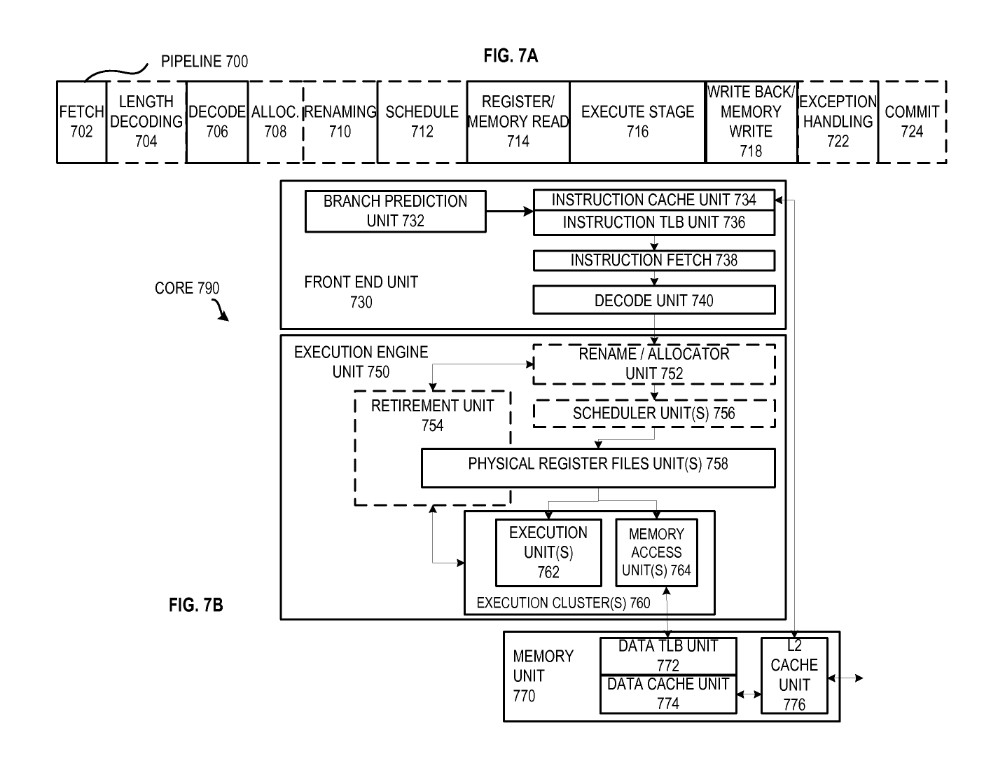

FIG. 7A is a block diagram illustrating both an exemplary in-order pipeline and an exemplary register renaming, out-of-order issue/execution pipeline according to embodiments of the invention. FIG. 7B is a block diagram illustrating both an exemplary embodiment of an in-order architecture core and an exemplary register renaming, out-of-order issue/execution architecture core to be included in a processor according to embodiments of the invention. The solid lined boxes in FIGS. 7A-B illustrate the in-order pipeline and in-order core, while the optional addition of the dashed lined boxes illustrates the register renaming, out-of-order issue/execution pipeline and core. Given that the in-order aspect is a subset of the out-of-order aspect, the out-of-order aspect will be described.

In FIG. 7A, a processor pipeline 700 includes a fetch stage 702, a length decode stage 704, a decode stage 706, an allocation stage 708, a renaming stage 710, a scheduling (also known as a dispatch or issue) stage 712, a register read/memory read stage 714, an execute stage 716, a write back/memory write stage 718, an exception handling stage 722, and a commit stage 724.

FIG. 7B shows processor core 790 including a front end unit 730 coupled to an execution engine unit 750, and both are coupled to a memory unit 770. The core 790 may be a reduced instruction set computing (RISC) core, a complex instruction set computing (CISC) core, a very long instruction word (VLIW) core, or a hybrid or alternative core type. As yet another option, the core 790 may be a special-purpose core, such as, for example, a network or communication core, compression engine, coprocessor core, general purpose computing graphics processing unit (GPGPU) core, graphics core, or the like.

The front end unit 730 includes a branch prediction unit 732 coupled to an instruction cache unit 734, which is coupled to an instruction translation lookaside buffer (TLB) 736, which is coupled to an instruction fetch unit 738, which is coupled to a decode unit 740. The decode unit 740 (or decoder) may decode instructions, and generate as an output one or more micro-operations, micro-code entry points, microinstructions, other instructions, or other control signals, which are decoded from, or which otherwise reflect, or are derived from, the original instructions. The decode unit 740 may be implemented using various different mechanisms. Examples of suitable mechanisms include, but are not limited to, look-up tables, hardware implementations, programmable logic arrays (PLAs), microcode read only memories (ROMs), etc. In one embodiment, the core 790 includes a microcode ROM or other medium that stores microcode for certain macroinstructions (e.g., in decode unit 740 or otherwise within the front end unit 730). The decode unit 740 is coupled to a rename/allocator unit 752 in the execution engine unit 750.

The execution engine unit 750 includes the rename/allocator unit 752 coupled to a retirement unit 754 and a set of one or more scheduler unit(s) 756. The scheduler unit(s) 756 represents any number of different schedulers, including reservations stations, central instruction window, etc. The scheduler unit(s) 756 is coupled to the physical register file(s) unit(s) 758. Each of the physical register file(s) units 758 represents one or more physical register files, different ones of which store one or more different data types, such as scalar integer, scalar floating point, packed integer, packed floating point, vector integer, vector floating point, status (e.g., an instruction pointer that is the address of the next instruction to be executed), etc. In one embodiment, the physical register file(s) unit 758 comprises a vector registers unit, a write mask registers unit, and a scalar registers unit. These register units may provide architectural vector registers, vector mask registers, and general purpose registers. The physical register file(s) unit(s) 758 is overlapped by the retirement unit 754 to illustrate various ways in which register renaming and out-of-order execution may be implemented (e.g., using a reorder buffer(s) and a retirement register file(s); using a future file(s), a history buffer(s), and a retirement register file(s); using a register maps and a pool of registers; etc.). The retirement unit 754 and the physical register file(s) unit(s) 758 are coupled to the execution cluster(s) 760. The execution cluster(s) 760 includes a set of one or more execution units 762 and a set of one or more memory access units 764. The execution units 762 may perform various operations (e.g., shifts, addition, subtraction, multiplication) and on various types of data (e.g., scalar floating point, packed integer, packed floating point, vector integer, vector floating point). While some embodiments may include a number of execution units dedicated to specific functions or sets of functions, other embodiments may include only one execution unit or multiple execution units that all perform all functions. The scheduler unit(s) 756, physical register file(s) unit(s) 758, and execution cluster(s) 760 are shown as being possibly plural because certain embodiments create separate pipelines for certain types of data/operations (e.g., a scalar integer pipeline, a scalar floating point/packed integer/packed floating point/vector integer/vector floating point pipeline, and/or a memory access pipeline that each have their own scheduler unit, physical register file(s) unit, and/or execution cluster—and in the case of a separate memory access pipeline, certain embodiments are implemented in which only the execution cluster of this pipeline has the memory access unit(s) 764). It should also be understood that where separate pipelines are used, one or more of these pipelines may be out-of-order issue/execution and the rest in-order.

The set of memory access units 764 is coupled to the memory unit 770, which includes a data TLB unit 772 coupled to a data cache unit 774 coupled to a level 2 (L2) cache unit 776. In one exemplary embodiment, the memory access units 764 may include a load unit, a store address unit, and a store data unit, each of which is coupled to the data TLB unit 772 in the memory unit 770. The instruction cache unit 734 is further coupled to a level 2 (L2) cache unit 776 in the memory unit 770. The L2 cache unit 776 is coupled to one or more other levels of cache and eventually to a main memory.

By way of example, the exemplary register renaming, out-of-order issue/execution core architecture may implement the pipeline 700 as follows: 1) the instruction fetch 738 performs the fetch and length decoding stages 702 and 704; 2) the decode unit 740 performs the decode stage 706; 3) the rename/allocator unit 752 performs the allocation stage 708 and renaming stage 710; 4) the scheduler unit(s) 756 performs the schedule stage 712; 5) the physical register file(s) unit(s) 758 and the memory unit 770 perform the register read/memory read stage 714; the execution cluster 760 perform the execute stage 716; 6) the memory unit 770 and the physical register file(s) unit(s) 758 perform the write back/memory write stage 718; 7) various units may be involved in the exception handling stage 722; and 8) the retirement unit 754 and the physical register file(s) unit(s) 758 perform the commit stage 724.

The core 790 may support one or more instructions sets (e.g., the x86 instruction set (with some extensions that have been added with newer versions); the MIPS instruction set of MIPS Technologies of Sunnyvale, Calif.; the ARM instruction set (with optional additional extensions such as NEON) of ARM Holdings of Sunnyvale, Calif.), including the instruction(s) described herein. In one embodiment, the core 790 includes logic to support a packed data instruction set extension (e.g., AVX1, AVX2), thereby allowing the operations used by many multimedia applications to be performed using packed data.

It should be understood that the core may support multithreading (executing two or more parallel sets of operations or threads), and may do so in a variety of ways including time sliced multithreading, simultaneous multithreading (where a single physical core provides a logical core for each of the threads that physical core is simultaneously multithreading), or a combination thereof (e.g., time sliced fetching and decoding and simultaneous multithreading thereafter such as in the Intel® Hyperthreading technology).

While register renaming is described in the context of out-of-order execution, it should be understood that register renaming may be used in an in-order architecture. While the illustrated embodiment of the processor also includes separate instruction and data cache units 734/774 and a shared L2 cache unit 776, alternative embodiments may have a single internal cache for both instructions and data, such as, for example, a Level 1 (L1) internal cache, or multiple levels of internal cache. In some embodiments, the system may include a combination of an internal cache and an external cache that is external to the core and/or the processor. Alternatively, all of the cache may be external to the core and/or the processor.

Specific Exemplary In-Order Core Architecture

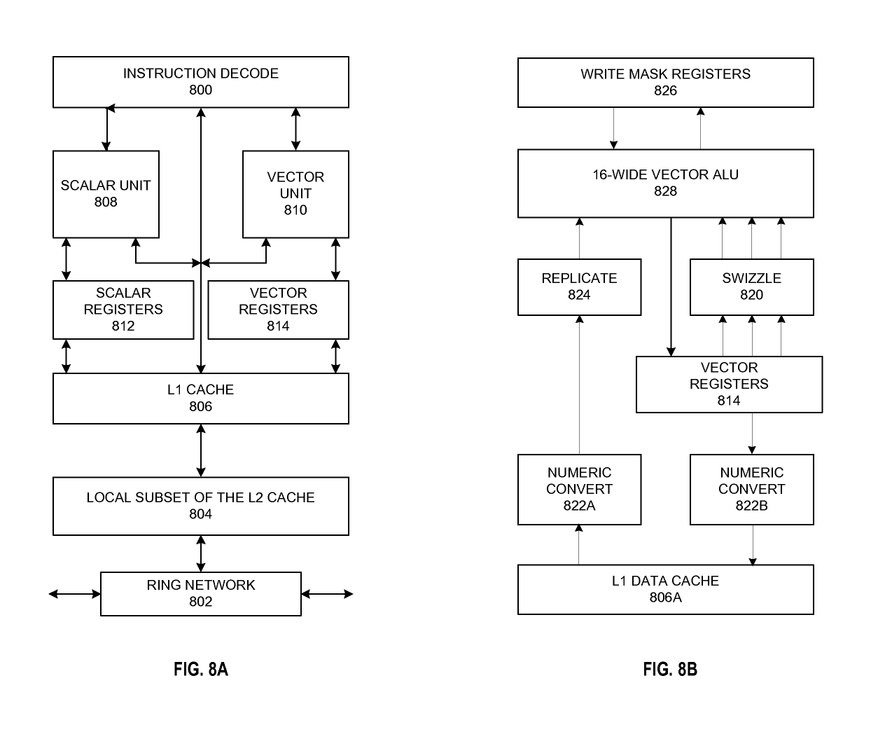

FIGS. 8A-B illustrate a block diagram of a more specific exemplary in-order core architecture, which core would be one of several logic blocks (including other cores of the same type and/or different types) in a chip. The logic blocks communicate through a high-bandwidth interconnect network (e.g., a ring network) with some fixed function logic, memory I/O interfaces, and other necessary I/O logic, depending on the application.

FIG. 8A is a block diagram of a single processor core, along with its connection to the on-die interconnect network 802 and with its local subset of the Level 2 (L2) cache 804, according to embodiments of the invention. In one embodiment, an instruction decoder 800 supports the x86 instruction set with a packed data instruction set extension. An L1 cache 806 allows low-latency accesses to cache memory into the scalar and vector units. While in one embodiment (to simplify the design), a scalar unit 808 and a vector unit 810 use separate register sets (respectively, scalar registers 812 and vector registers 814) and data transferred between them is written to memory and then read back in from a level 1 (L1) cache 806, alternative embodiments of the invention may use a different approach (e.g., use a single register set or include a communication path that allow data to be transferred between the two register files without being written and read back).

The local subset of the L2 cache 804 is part of a global L2 cache that is divided into separate local subsets, one per processor core. Each processor core has a direct access path to its own local subset of the L2 cache 804. Data read by a processor core is stored in its L2 cache subset 804 and can be accessed quickly, in parallel with other processor cores accessing their own local L2 cache subsets. Data written by a processor core is stored in its own L2 cache subset 804 and is flushed from other subsets, if necessary. The ring network ensures coherency for shared data. The ring network is bi-directional to allow agents such as processor cores, L2 caches and other logic blocks to communicate with each other within the chip. Each ring data-path is 1012-bits wide per direction.

FIG. 8B is an expanded view of part of the processor core in FIG. 8A according to embodiments of the invention. FIG. 8B includes an L1 data cache 806A part of the L1 cache 804, as well as more detail regarding the vector unit 810 and the vector registers 814. Specifically, the vector unit 810 is a 16-wide vector processing unit (VPU) (see the 16-wide ALU 828), which executes one or more of integer, single-precision float, and double-precision float instructions. The VPU supports swizzling the register inputs with swizzle unit 820, numeric conversion with numeric convert units 822A-B, and replication with replication unit 824 on the memory input. Write mask registers 826 allow predicating resulting vector writes.

Processor with Integrated Memory Controller and Graphics

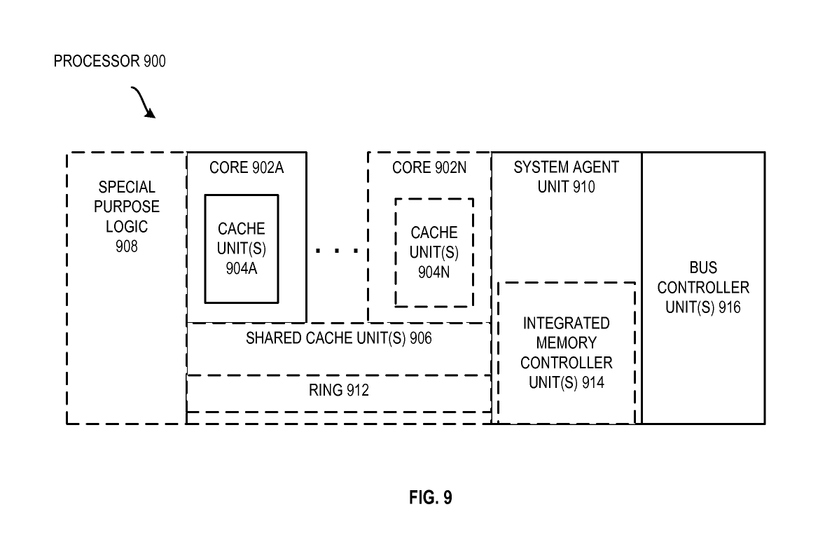

FIG. 9 is a block diagram of a processor 900 that may have more than one core, may have an integrated memory controller, and may have integrated graphics according to embodiments of the invention. The solid lined boxes in FIG. 9 illustrate a processor 900 with a single core 902A, a system agent 910, a set of one or more bus controller units 916, while the optional addition of the dashed lined boxes illustrates an alternative processor 900 with multiple cores 902A-N, a set of one or more integrated memory controller unit(s) 914 in the system agent unit 910, and special purpose logic 908.

Thus, different implementations of the processor 900 may include: 1) a CPU with the special purpose logic 908 being integrated graphics and/or scientific (throughput) logic (which may include one or more cores), and the cores 902A-N being one or more general purpose cores (e.g., general purpose in-order cores, general purpose out-of-order cores, a combination of the two); 2) a coprocessor with the cores 902A-N being a large number of special purpose cores intended primarily for graphics and/or scientific (throughput); and 3) a coprocessor with the cores 902A-N being a large number of general purpose in-order cores. Thus, the processor 900 may be a general-purpose processor, coprocessor or special-purpose processor, such as, for example, a network or communication processor, compression engine, graphics processor, GPGPU (general purpose graphics processing unit), a high-throughput many integrated core (MIC) coprocessor (including 30 or more cores), embedded processor, or the like. The processor may be implemented on one or more chips. The processor 900 may be a part of and/or may be implemented on one or more substrates using any of a number of process technologies, such as, for example, BiCMOS, CMOS, or NMOS.

The memory hierarchy includes one or more levels of cache within the cores, a set or one or more shared cache units 906, and external memory (not shown) coupled to the set of integrated memory controller units 914. The set of shared cache units 906 may include one or more mid-level caches, such as level 2 (L2), level 3 (L3), level 4 (L4), or other levels of cache, a last level cache (LLC), and/or combinations thereof. While in one embodiment a ring based interconnect unit 912 interconnects the integrated graphics logic 908, the set of shared cache units 906, and the system agent unit 910/integrated memory controller unit(s) 914, alternative embodiments may use any number of well-known techniques for interconnecting such units. In one embodiment, coherency is maintained between one or more cache units 906 and cores 902-A-N.

In some embodiments, one or more of the cores 902A-N are capable of multi-threading. The system agent 910 includes those components coordinating and operating cores 902A-N. The system agent unit 910 may include for example a power control unit (PCU) and a display unit. The PCU may be or include logic and components needed for regulating the power state of the cores 902A-N and the integrated graphics logic 908. The display unit is for driving one or more externally connected displays.

The cores 902A-N may be homogenous or heterogeneous in terms of architecture instruction set; that is, two or more of the cores 902A-N may be capable of execution the same instruction set, while others may be capable of executing only a subset of that instruction set or a different instruction set.

Exemplary Computer Architectures

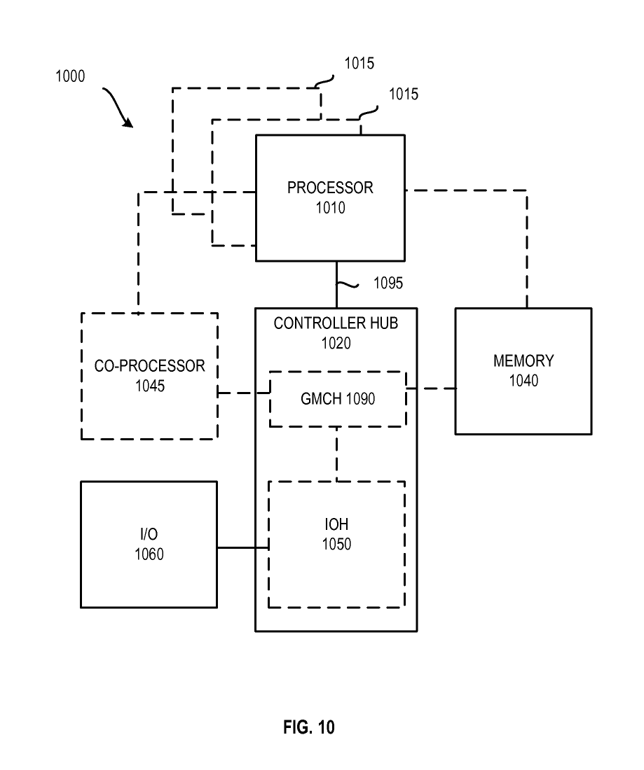

FIGS. 10-13 are block diagrams of exemplary computer architectures. Other system designs and configurations known in the arts for laptops, desktops, handheld PCs, personal digital assistants, engineering workstations, servers, network devices, network hubs, switches, embedded processors, digital signal processors (DSPs), graphics devices, video game devices, set-top boxes, micro controllers, cell phones, portable media players, hand held devices, and various other electronic devices, are also suitable. In general, a huge variety of systems or electronic devices capable of incorporating a processor and/or other execution logic as disclosed herein are generally suitable.

Referring now to FIG. 10, shown is a block diagram of a system 1000 in accordance with one embodiment of the present invention. The system 1000 may include one or more processors 1010, 1015, which are coupled to a controller hub 1020. In one embodiment the controller hub 1020 includes a graphics memory controller hub (GMCH) 1090 and an Input/Output Hub (IOH) 1050 (which may be on separate chips); the GMCH 1090 includes memory and graphics controllers to which are coupled memory 1040 and a coprocessor 1045; the IOH 1050 is couples input/output (I/O) devices 1060 to the GMCH 1090. Alternatively, one or both of the memory and graphics controllers are integrated within the processor (as described herein), the memory 1040 and the coprocessor 1045 are coupled directly to the processor 1010, and the controller hub 1020 in a single chip with the IOH 1050.

The optional nature of additional processors 1015 is denoted in FIG. 10 with broken lines. Each processor 1010, 1015 may include one or more of the processing cores described herein and may be some version of the processor 900.

The memory 1040 may be, for example, dynamic random access memory (DRAM), phase change memory (PCM), or a combination of the two. For at least one embodiment, the controller hub 1020 communicates with the processor(s) 1010, 1015 via a multi-drop bus, such as a frontside bus (FSB), point-to-point interface such as QuickPath Interconnect (QPI), or similar connection 1095.

In one embodiment, the coprocessor 1045 is a special-purpose processor, such as, for example, a high-throughput MIC processor, a network or communication processor, compression engine, graphics processor, GPGPU, embedded processor, or the like. In one embodiment, controller hub 1020 may include an integrated graphics accelerator.

There can be a variety of differences between the physical resources 1010, 1015 in terms of a spectrum of metrics of merit including architectural, microarchitectural, thermal, power consumption characteristics, and the like.

In one embodiment, the processor 1010 executes instructions that control data processing operations of a general type. Embedded within the instructions may be coprocessor instructions. The processor 1010 recognizes these coprocessor instructions as being of a type that should be executed by the attached coprocessor 1045. Accordingly, the processor 1010 issues these coprocessor instructions (or control signals representing coprocessor instructions) on a coprocessor bus or other interconnect, to coprocessor 1045. Coprocessor(s) 1045 accept and execute the received coprocessor instructions.

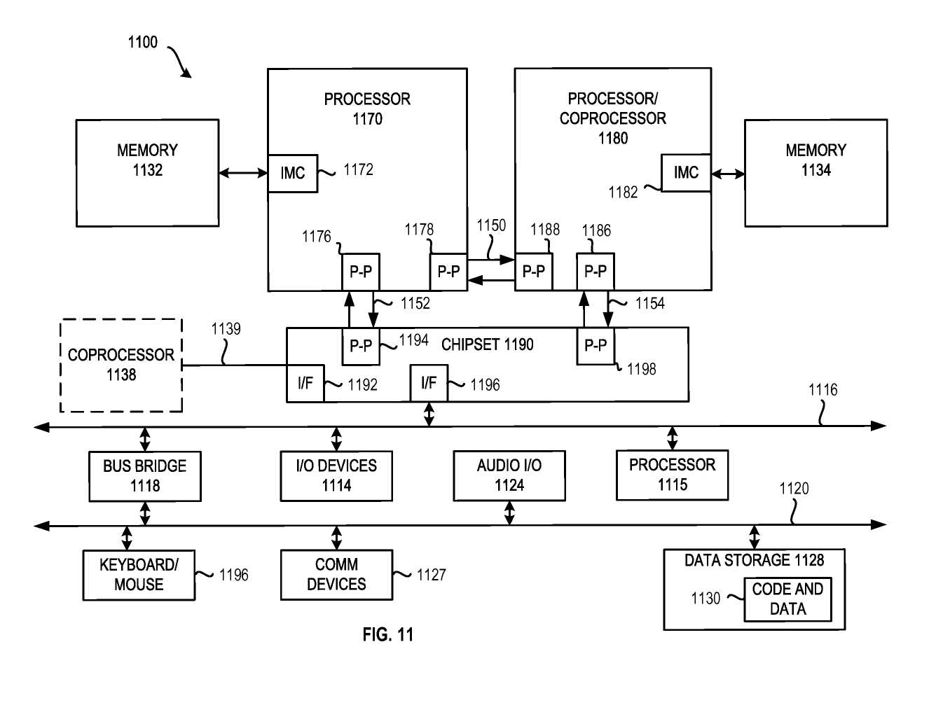

Referring now to FIG. 11, shown is a block diagram of a first more specific exemplary system 1100 in accordance with an embodiment of the present invention. As shown in FIG. 11, multiprocessor system 1100 is a point-to-point interconnect system, and includes a first processor 1170 and a second processor 1180 coupled via a point-to-point interconnect 1150. Each of processors 1170 and 1180 may be some version of the processor 900. In one embodiment of the invention, processors 1170 and 1180 are respectively processors 1010 and 1015, while coprocessor 1138 is coprocessor 1045. In another embodiment, processors 1170 and 1180 are respectively processor 1010 coprocessor 1045.

Processors 1170 and 1180 are shown including integrated memory controller (IMC) units 1172 and 1182, respectively. Processor 1170 also includes as part of its bus controller units point-to-point (P-P) interfaces 1176 and 1178; similarly, second processor 1180 includes P-P interfaces 1186 and 1188. Processors 1170, 1180 may exchange information via a point-to-point (P-P) interface 1150 using P-P interface circuits 1178, 1188. As shown in FIG. 11, IMCs 1172 and 1182 couple the processors to respective memories, namely a memory 1132 and a memory 1134, which may be portions of main memory locally attached to the respective processors.

Processors 1170, 1180 may each exchange information with a chipset 1190 via individual P-P interfaces 1152, 1154 using point to point interface circuits 1176, 1194, 1186, 1198. Chipset 1190 may optionally exchange information with the coprocessor 1138 via a high-performance interface 1139. In one embodiment, the coprocessor 1138 is a special-purpose processor, such as, for example, a high-throughput MIC processor, a network or communication processor, compression engine, graphics processor, GPGPU, embedded processor, or the like.

A shared cache (not shown) may be included in either processor or outside of both processors, yet connected with the processors via P-P interconnect, such that either or both processors' local cache information may be stored in the shared cache if a processor is placed into a low power mode.

Chipset 1190 may be coupled to a first bus 1116 via an interface 1196. In one embodiment, first bus 1116 may be a Peripheral Component Interconnect (PCI) bus, or a bus such as a PCI Express bus or another third generation I/O interconnect bus, although the scope of the present invention is not so limited.

As shown in FIG. 11, various I/O devices 1114 may be coupled to first bus 1116, along with a bus bridge 1118 which couples first bus 1116 to a second bus 1120. In one embodiment, one or more additional processor(s) 1115, such as coprocessors, high-throughput MIC processors, GPGPU's, accelerators (such as, e.g., graphics accelerators or digital signal processing (DSP) units), field programmable gate arrays, or any other processor, are coupled to first bus 1116. In one embodiment, second bus 1120 may be a low pin count (LPC) bus. Various devices may be coupled to a second bus 1120 including, for example, a keyboard and/or mouse 1122, communication devices 1127 and a storage unit 1128 such as a disk drive or other mass storage device which may include instructions/code and data 1130, in one embodiment. Further, an audio I/O 1124 may be coupled to the second bus 1120. Note that other architectures are possible. For example, instead of the point-to-point architecture of FIG. 11, a system may implement a multi-drop bus or other such architecture.

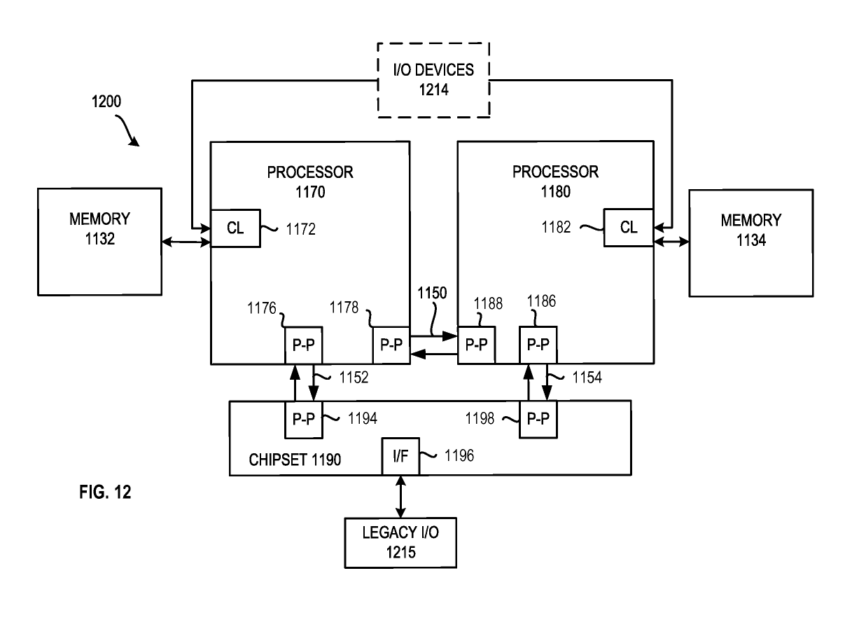

Referring now to FIG. 12, shown is a block diagram of a second more specific exemplary system 1200 in accordance with an embodiment of the present invention. Like elements in FIGS. 11 and 12 bear like reference numerals, and certain aspects of FIG. 11 have been omitted from FIG. 12 in order to avoid obscuring other aspects of FIG. 12.

FIG. 12 illustrates that the processors 1170, 1180 may include integrated memory and I/O control logic (“CL”) 1172 and 1182, respectively. Thus, the CL 1172, 1182 include integrated memory controller units and include I/O control logic. FIG. 12 illustrates that not only are the memories 1132, 1134 coupled to the CL 1172, 1182, but also that I/O devices 1214 are also coupled to the control logic 1172, 1182. Legacy I/O devices 1215 are coupled to the chip set 1190.

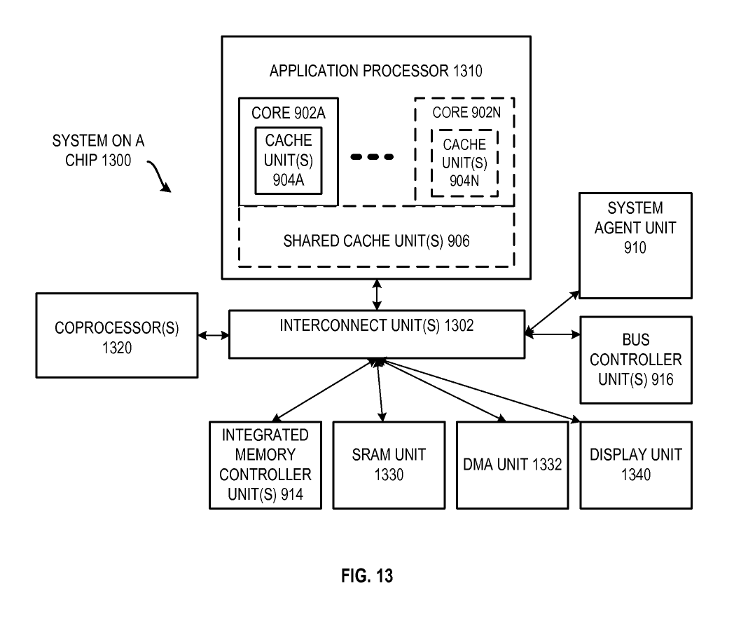

Referring now to FIG. 13, shown is a block diagram of a SoC 1300 in accordance with an embodiment of the present invention. Similar elements in FIG. 9 bear like reference numerals. Also, dashed lined boxes are optional features on more advanced SoCs. In FIG. 13, an interconnect unit(s) 1302 is coupled to: an application processor 1310 which includes a set of one or more cores 202A-N and shared cache unit(s) 906; a system agent unit 910; a bus controller unit(s) 916; an integrated memory controller unit(s) 914; a set or one or more coprocessors 1320 which may include integrated graphics logic, an image processor, an audio processor, and a video processor; an static random access memory (SRAM) unit 1330; a direct memory access (DMA) unit 1332; and a display unit 1340 for coupling to one or more external displays. In one embodiment, the coprocessor(s) 1320 include a special-purpose processor, such as, for example, a network or communication processor, compression engine, GPGPU, a high-throughput MIC processor, embedded processor, or the like.

Embodiments of the mechanisms disclosed herein may be implemented in hardware, software, firmware, or a combination of such implementation approaches. Embodiments of the invention may be implemented as computer programs or program code executing on programmable systems comprising at least one processor, a storage system (including volatile and non-volatile memory and/or storage elements), at least one input device, and at least one output device.

Program code, such as code 1130 illustrated in FIG. 11, may be applied to input instructions to perform the functions described herein and generate output information. The output information may be applied to one or more output devices, in known fashion. For purposes of this application, a processing system includes any system that has a processor, such as, for example; a digital signal processor (DSP), a microcontroller, an application specific integrated circuit (ASIC), or a microprocessor.

The program code may be implemented in a high level procedural or object oriented programming language to communicate with a processing system. The program code may also be implemented in assembly or machine language, if desired. In fact, the mechanisms described herein are not limited in scope to any particular programming language. In any case, the language may be a compiled or interpreted language.

One or more aspects of at least one embodiment may be implemented by representative instructions stored on a machine-readable medium which represents various logic within the processor, which when read by a machine causes the machine to fabricate logic to perform the techniques described herein. Such representations, known as “IP cores” may be stored on a tangible, machine readable medium and supplied to various customers or manufacturing facilities to load into the fabrication machines that actually make the logic or processor.

Such machine-readable storage media may include, without limitation, non-transitory, tangible arrangements of articles manufactured or formed by a machine or device, including storage media such as hard disks, any other type of disk including floppy disks, optical disks, compact disk read-only memories (CD-ROMs), compact disk rewritable's (CD-RWs), and magneto-optical disks, semiconductor devices such as read-only memories (ROMs), random access memories (RAMs) such as dynamic random access memories (DRAMs), static random access memories (SRAMs), erasable programmable read-only memories (EPROMs), flash memories, electrically erasable programmable read-only memories (EEPROMs), phase change memory (PCM), magnetic or optical cards, or any other type of media suitable for storing electronic instructions.

Accordingly, embodiments of the invention also include non-transitory, tangible machine-readable media containing instructions or containing design data, such as Hardware Description Language (HDL), which defines structures, circuits, apparatuses, processors and/or system features described herein. Such embodiments may also be referred to as program products.

Emulation (Including Binary Translation, Code Morphing, Etc.)

In some cases, an instruction converter may be used to convert an instruction from a source instruction set to a target instruction set. For example, the instruction converter may translate (e.g., using static binary translation, dynamic binary translation including dynamic compilation), morph, emulate, or otherwise convert an instruction to one or more other instructions to be processed by the core. The instruction converter may be implemented in software, hardware, firmware, or a combination thereof. The instruction converter may be on processor, off processor, or part on and part off processor.

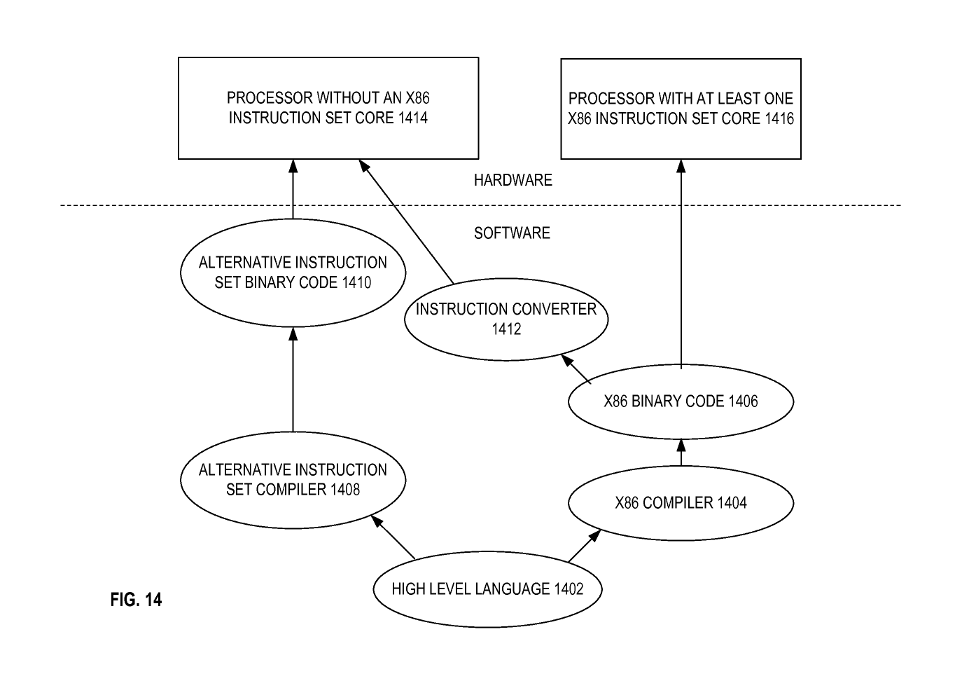

FIG. 14 is a block diagram contrasting the use of a software instruction converter to convert binary instructions in a source instruction set to binary instructions in a target instruction set according to embodiments of the invention. In the illustrated embodiment, the instruction converter is a software instruction converter, although alternatively the instruction converter may be implemented in software, firmware, hardware, or various combinations thereof. FIG. 14 shows a program in a high level language 1402 may be compiled using an x86 compiler 1404 to generate x86 binary code 1406 that may be natively executed by a processor with at least one x86 instruction set core 1416. The processor with at least one x86 instruction set core 1416 represents any processor that can perform substantially the same functions as an Intel processor with at least one x86 instruction set core by compatibly executing or otherwise processing (1) a substantial portion of the instruction set of the Intel x86 instruction set core or (2) object code versions of applications or other software targeted to run on an Intel processor with at least one x86 instruction set core, in order to achieve substantially the same result as an Intel processor with at least one x86 instruction set core. The x86 compiler 1404 represents a compiler that is operable to generate x86 binary code 1406 (e.g., object code) that can, with or without additional linkage processing, be executed on the processor with at least one x86 instruction set core 1416. Similarly, FIG. 14 shows the program in the high level language 1402 may be compiled using an alternative instruction set compiler 1408 to generate alternative instruction set binary code 1410 that may be natively executed by a processor without at least one x86 instruction set core 1414 (e.g., a processor with cores that execute the MIPS instruction set of MIPS Technologies of Sunnyvale, Calif. and/or that execute the ARM instruction set of ARM Holdings of Sunnyvale, Calif.). The instruction converter 1412 is used to convert the x86 binary code 1406 into code that may be natively executed by the processor without an x86 instruction set core 1414. This converted code is not likely to be the same as the alternative instruction set binary code 1410 because an instruction converter capable of this is difficult to make; however, the converted code will accomplish the general operation and be made up of instructions from the alternative instruction set. Thus, the instruction converter 1412 represents software, firmware, hardware, or a combination thereof that, through emulation, simulation or any other process, allows a processor or other electronic device that does not have an x86 instruction set processor or core to execute the x86 binary code 1406.

Components, features, and details described for any of FIGS. 1, 3, and 4 may also optionally apply to any of FIGS. 2, 5, and 6. Moreover, components, features, and details described for any of the apparatus may also optionally apply to any of the methods, which in embodiments may be performed by and/or with such apparatus. Any of the processors described herein may be included in any of the computer systems disclosed herein (e.g., FIGS. 10-13). In some embodiments, the computer system may include a dynamic random access memory (DRAM). Alternatively, the computer system may include a type of volatile memory that does not need to be refreshed or flash memory.

In the description and claims, the terms “coupled” and/or “connected,” along with their derivatives, may have be used. These terms are not intended as synonyms for each other. Rather, in embodiments, “connected” may be used to indicate that two or more elements are in direct physical and/or electrical contact with each other. “Coupled” may mean that two or more elements are in direct physical and/or electrical contact with each other. However, “coupled” may also mean that two or more elements are not in direct contact with each other, but yet still co-operate or interact with each other. For example, a MMU may be coupled with a TLB through one or more intervening components. In the figures, arrows are used to show connections and couplings.

The term “and/or” may have been used. As used herein, the term “and/or” means one or the other or both (e.g., A and/or B means A or B or both A and B).

In the description above, specific details have been set forth in order to provide a thorough understanding of the embodiments. However, other embodiments may be practiced without some of these specific details. The scope of the invention is not to be determined by the specific examples provided above, but only by the claims below. In other instances, well-known circuits, structures, devices, and operations have been shown in block diagram form and/or without detail in order to avoid obscuring the understanding of the description. Where considered appropriate, reference numerals, or terminal portions of reference numerals, have been repeated among the figures to indicate corresponding or analogous elements, which may optionally have similar or the same characteristics, unless specified or clearly apparent otherwise.

Some embodiments include an article of manufacture (e.g., a computer program product) that includes a machine-readable medium. The medium may include a mechanism that provides, for example stores, information in a form that is readable by the machine. The machine-readable medium may provide, or have stored thereon, an instruction or sequence of instructions, that if and/or when executed by a machine are operative to cause the machine to perform and/or result in the machine performing one or operations, methods, or techniques disclosed herein.

In some embodiments, the machine-readable medium may include a non-transitory machine-readable storage medium. For example, the non-transitory machine-readable storage medium may include a floppy diskette, an optical storage medium, an optical disk, an optical data storage device, a CD-ROM, a magnetic disk, a magneto-optical disk, a read only memory (ROM), a programmable ROM (PROM), an erasable-and-programmable ROM (EPROM), an electrically-erasable-and-programmable ROM (EEPROM), a random access memory (RAM), a static-RAM (SRAM), a dynamic-RAM (DRAM), a Flash memory, a phase-change memory, a phase-change data storage material, a non-volatile memory, a non-volatile data storage device, a non-transitory memory, a non-transitory data storage device, or the like. The non-transitory machine-readable storage medium does not consist of a transitory propagated signal. In some embodiments, the storage medium may include a tangible medium that includes solid matter.

Examples of suitable machines include, but are not limited to, a general-purpose processor, a special-purpose processor, a digital logic circuit, an integrated circuit, or the like. Still other examples of suitable machines include a computer system or other electronic device that includes a processor, a digital logic circuit, or an integrated circuit. Examples of such computer systems or electronic devices include, but are not limited to, desktop computers, laptop computers, notebook computers, tablet computers, netbooks, smartphones, cellular phones, servers, network devices (e.g., routers and switches.), Mobile Internet devices (MIDs), media players, smart televisions, nettops, set-top boxes, and video game controllers.

Reference throughout this specification to “one embodiment,” “an embodiment,” “one or more embodiments,” “some embodiments,” for example, indicates that a particular feature may be included in the practice of the invention but is not necessarily required to be. Similarly, in the description various features are sometimes grouped together in a single embodiment, Figure, or description thereof for the purpose of streamlining the disclosure and aiding in the understanding of various inventive aspects. This method of disclosure, however, is not to be interpreted as reflecting an intention that the invention requires more features than are expressly recited in each claim. Rather, as the following claims reflect, inventive aspects lie in less than all features of a single disclosed embodiment. Thus, the claims following the Detailed Description are hereby expressly incorporated into this Detailed Description, with each claim standing on its own as a separate embodiment of the invention.

### EXAMPLE EMBODIMENTS

The following examples pertain to further embodiments. Specifics in the examples may be used anywhere in one or more embodiments.

Example 1 is a processor that includes at least one translation lookaside buffer (TLB). Each TLB is to store translations of logical addresses to corresponding physical addresses. The processor also includes a memory management unit (MMU). The MMU, in response to a miss in the at least one TLB for a translation of a first logical address to a corresponding physical address, is to check for a multi-page protected container page versus regular page (P/R) check hint. If the multi-page P/R check hint is found, then the processor is to check a P/R indication. If the multi-page P/R check hint is not found, the processor does not check the P/R indication.

Example 2 includes the processor of Example 1, in which the MMU is to find the multi-page P/R check hint, and in which the multi-page P/R check hint is to apply to a plurality of pages.

Example 3 includes the processor of Example 1, in which the MMU is to find the multi-page P/R check hint, and in which the multi-page P/R check hint is to apply to an entire logical address space of a process that is to correspond to the first logical address.

Example 4 includes the processor of Example 1, in which the MMU is to find the multi-page P/R check hint in one of a page directory base register, a core control register, and a processor context switch state save area.

Example 5 includes the processor of Example 1, in which the MMU is to find the multi-page P/R check hint, and in which the multi-page P/R check hint is to apply to a logical address range which is to be a subset of an entire logical address range of a process that is to correspond to the first logical address.

Example 6 includes the processor of Example 1, in which the MMU is to find the multi-page P/R check hint in a hierarchical paging structure that is to be at a hierarchical level between a page directory base register and a page table.

Example 7 includes the processor of Example 6, in which the multi-page P/R check hint is to be stored in a page directory table.

Example 8 includes the processor of Example 6, in which the multi-page P/R check hint is to be stored in a page directory pointer table.

Example 9 includes the processor of Example 6, in which the multi-page P/R check hint is to be stored in one of a directory of page directory pointer tables entry, a page-directory-pointer table (PDPT) entry, and a page-directory table (PD) entry.

Example 10 includes the processor of any one of Examples 1 to 9, in which the MMU is to find the multi-page P/R check hint, and in which the MMU is to check the P/R indication which is to be an EPCM.E bit in an enclave page cache map (EPCM).

Example 11 includes the processor of any one of Examples 1 to 9, in which the MMU is to check for the multi-page P/R check hint which is to indicate whether the MMU is to check for the P/R indication of whether a page corresponding to the first logical address is a regular page or a secure enclave page.

Example 12 includes the processor of any one of Examples 1 to 9, in which the MMU is to: (1) if the multi-page P/R check hint is found, then store an indication of whether a page corresponding to the first logical address is a protected container page, as indicated by the P/R indication, in a TLB entry in the at least one TLB; and (2) if the multi-page P/R check hint is not found, then store an indication that the page is a regular page in the TLB entry.

Example 13 includes the processor of any one of Examples 1 to 9, in which the MMU is to find the multi-page P/R check hint, and further including a memory access unit and a memory encryption and decryption unit, in which: (1) the memory encryption and decryption unit is to access a page corresponding to the first logical address if the P/R indication is to indicate that the page is a protected container page; and (2) the memory access unit is to access the page, bypassing the memory encryption and decryption unit, if the P/R indication is to indicate that the page is a regular page.

Example 14 includes the processor of any one of Examples 1 to 9, further including at least one model specific register, and in which the processor is to determine at least one location where the MMU is to check for the P/R check hint in the at least one model specific register.

Example 15 is an apparatus to manage pages that includes a protected container page versus regular page conversion module. The conversion module is to convert protected container pages to regular pages, and is to convert regular pages to protected container pages. The apparatus also includes a multi-page protected container page versus regular page (P/R) check hint module communicatively coupled with the conversion module. The multi-page P/R check hint module is to store a multi-page P/R check hint. The multi-page P/R check hint is to provide a hint to a processor of whether the processor is to check P/R indications for multiple pages.

Example 16 includes the apparatus of Example 15, in which the multi-page P/R check hint module is to store the multi-page P/R check hint which is to apply to an entire logical address space of a process.

Example 17 includes the apparatus of Example 15, in which the multi-page P/R check hint module is to store the multi-page P/R check hint which is to apply to a logical address range that is to be a subset of an entire logical address range of a process.

Example 18 includes the apparatus of Example 15, in which the multi-page P/R check hint module is to store the multi-page P/R check hint in one of a page directory base register and a hierarchical paging structure that is to be at a hierarchical level between the page directory base register and a page table.

Example 19 includes the apparatus of Example 15, in which the conversion module includes a protected container page grouper module to group protected container pages in pages hierarchically below an entry in a set of hierarchical paging structures, and in which the multi-page P/R check hint module is to store the multi-page P/R check hint in the entry.

Example 20 includes the apparatus of any one of Examples 15 to 19, in which the multi-page P/R check hint module includes a P/R check hint location determination module to determine a location of a plurality of different possible locations to provide the P/R check hint which encompasses all protected container pages but not all regular pages.

Example 21 includes the apparatus of any one of Examples 15 to 19, in which conversion module is to store the P/R indications in an enclave page cache map (EPCM).

Example 22 is an article of manufacture including a non-transitory machine-readable storage medium. The non-transitory machine-readable storage medium stores instructions that, if executed by a machine, are to cause the machine to perform operations including convert pages between protected container pages and regular pages, and provide a multi-page protected container page versus regular page (P/R) check hint to a processor. The multi-page P/R check hint is to hint to the processor to check P/R indications for multiple pages.

Example 23 includes the article of manufacture of Example 22, in which the instructions to provide the multi-page P/R check hint comprise instructions that if executed by the machine are to cause the machine to provide the multi-page P/R check hint which is to apply to an entire logical address space of a process.

Example 24 includes the article of manufacture of Example 22, in which the instructions to provide the multi-page P/R check hint comprise instructions that if executed by the machine are to cause the machine to provide the multi-page P/R check hint which is to apply to a logical address range that is to be a subset of an entire logical address range of a process.

Example 25 includes the article of manufacture of Example 22, in which the instructions to provide the multi-page P/R check hint comprise instructions that if executed by the machine are to cause the machine to store the multi-page P/R check hint in one of a page directory base register and a hierarchical paging structure selected from a page directory table and a page directory pointer table.

Example 26 includes the article of manufacture of any one of Examples 22 to 25, in which the storage medium further stores instructions that if executed by the machine are to cause the machine to perform operations including grouping protected container pages in pages hierarchically below an entry in a set of hierarchical paging structures.

Example 27 includes the article of manufacture of any one of Examples 22 to 25, in which the storage medium further stores instructions that if executed by the machine are to cause the machine to perform operations including determining a location, of a plurality of different possible locations, to provide the P/R check hint, which encompasses all protected container pages but not all regular pages.

Example 28 is a system to process instructions that includes an interconnect, and a dynamic random access memory (DRAM) coupled with the interconnect. The DRAM stores instructions that, if executed by the system, are to cause the system to perform operations including providing a multi-page protected container page versus regular page (P/R) check hint. The system also includes a processor coupled with the interconnect. The processor in conjunction with performing a page table walk is to check for the multi-page P/R check hint. If the multi-page P/R check hint is found, then the processor is to check a P/R indication, and if the multi-page P/R check hint is not found, then the processor is not to check the P/R indication.

Example 29 includes the system of Example 28, in which the processor is to find the multi-page P/R check hint in one of a page directory base register, a hierarchical paging structure that is to be at a hierarchical level between the page directory base register and a page table, and a state save area.

Example 30 includes the processor of any one of Examples 1 to 14, further including an optional branch prediction unit to predict branches, and an optional instruction prefetch unit, coupled with the branch prediction unit, the instruction prefetch unit to prefetch instructions including the instruction. The processor may also optionally include an optional level 1 (L1) instruction cache coupled with the instruction prefetch unit, the L1 instruction cache to store instructions, an optional L1 data cache to store data, and an optional level 2 (L2) cache to store data and instructions. The processor may also optionally include an instruction fetch unit coupled with the decode unit, the L1 instruction cache, and the L2 cache, to fetch the instruction, in some cases from one of the L1 instruction cache and the L2 cache, and to provide the instruction to the decode unit. The processor may also optionally include a register rename unit to rename registers, an optional scheduler to schedule one or more operations that have been decoded from the instruction for execution, and an optional commit unit to commit execution results of the instruction.

Example 31 is a processor or other apparatus substantially as described herein.

Example 32 is a processor or other apparatus that is operative to perform any method substantially as described herein.

What is claimed is:

1. A processor comprising:
at least one translation lookaside buffer (TLB), each TLB to store translations of logical addresses to corresponding physical addresses; and
a memory management unit (MMU), the MMU, in response to a miss in the at least one TLB for a translation of a first logical address to a corresponding physical address, to:
check for a multi-page protected container page versus regular page (P/R) check hint;
if the multi-page P/R check hint is found, then check a P/R indication; and
if the multi-page P/R check hint is not found, then do not check the P/R indication.

2. The processor of claim 1, wherein the MMU is to find the multi-page P/R check hint, and wherein the multi-page P/R check hint is to apply to a plurality of pages.

3. The processor of claim 1, wherein the MMU is to find the multi-page P/R check hint, and wherein the multi-page P/R check hint is to apply to an entire logical address space of a process that is to correspond to the first logical address.

4. The processor of claim 1, wherein the MMU is to find the multi-page P/R check hint in one of a page directory base register, a core control register, and a processor context switch state save area.

5. The processor of claim 1, wherein the MMU is to find the multi-page P/R check hint, and wherein the multi-page P/R check hint is to apply to a logical address range which is to be a subset of an entire logical address range of a process that is to correspond to the first logical address.

6. The processor of claim 1, wherein the MMU is to find the multi-page P/R check hint in a hierarchical paging structure that is to be at a hierarchical level between a page directory base register and a page table.

7. The processor of claim 6, wherein the multi-page P/R check hint is to be stored in a page directory table.

8. The processor of claim 6, wherein the multi-page P/R check hint is to be stored in a page directory pointer table.

9. The processor of claim 6, wherein the multi-page P/R check hint is to be stored in one of a directory of page directory pointer tables entry, a page-directory-pointer table (PDPT) entry, and a page-directory table (PD) entry.

10. The processor of claim 1, wherein the MMU is to find the multi-page P/R check hint, and wherein the MMU is to check the P/R indication which is to be an EPCM.E bit in an enclave page cache map (EPCM).

11. The processor of claim 1, wherein the MMU is to check for the multi-page P/R check hint which is to indicate whether the MMU is to check for the P/R indication of whether a page corresponding to the first logical address is a regular page or a secure enclave page.

12. The processor of claim 1, wherein the MMU is to:
if the multi-page P/R check hint is found, store an indication of whether a page corresponding to the first logical address is a protected container page, as indicated by the P/R indication, in a TLB entry in the at least one TLB; and
if the multi-page P/R check hint is not found, store an indication that the page is a regular page in the TLB entry.

13. The processor of claim 1, wherein the MMU is to find the multi-page P/R check hint, and further comprising a memory access unit and a memory encryption and decryption unit, wherein:
the memory encryption and decryption unit is to access a page corresponding to the first logical address if the P/R indication is to indicate that the page is a protected container page; and
the memory access unit is to access the page, bypassing the memory encryption and decryption unit, if the P/R indication is to indicate that the page is a regular page.

14. The processor of claim 1, further comprising at least one model specific register, and wherein the processor is to determine at least one location where the MMU is to check for the P/R check hint in the at least one model specific register.

15. An apparatus to manage pages comprising:
a protected container page versus regular page conversion module, the conversion module to convert protected container pages to regular pages, and to convert regular pages to protected container pages; and
a multi-page protected container page versus regular page (P/R) check hint module communicatively coupled with the conversion module, the multi-page P/R check hint module to store a multi-page P/R check hint, wherein the multi-page P/R check hint is to provide a hint to a processor of whether the processor is to check P/R indications for multiple pages.

16. The apparatus of claim 15, wherein the multi-page P/R check hint module is to store the multi-page P/R check hint which is to apply to an entire logical address space of a process.

17. The apparatus of claim 15, wherein the multi-page P/R check hint module is to store the multi-page P/R check hint which is to apply to a logical address range that is to be a subset of an entire logical address range of a process.

18. The apparatus of claim 15, wherein the multi-page P/R check hint module is to store the multi-page P/R check hint in one of a page directory base register and a hierarchical paging structure that is to be at a hierarchical level between the page directory base register and a page table.

19. The apparatus of claim 15, wherein the conversion module comprises a protected container page grouper module to group protected container pages in pages hierarchically below an entry in a set of hierarchical paging structures, and wherein the multi-page P/R check hint module is to store the multi-page P/R check hint in the entry.

20. An article of manufacture comprising a non-transitory machine-readable storage medium, the non-transitory machine-readable storage medium storing instructions that if executed by a machine are to cause the machine to perform operations comprising:
convert pages between protected container pages and regular pages; and
provide a multi-page protected container page versus regular page (P/R) check hint to a processor, wherein the multi-page P/R check hint is to hint to the processor to check P/R indications for multiple pages.

21. The article of manufacture of claim 20, wherein the instructions to provide the multi-page P/R check hint comprise instructions that if executed by the machine are to cause the machine to provide the multi-page P/R check hint which is to apply to an entire logical address space of a process.

22. The article of manufacture of claim 20, wherein the instructions to provide the multi-page P/R check hint comprise instructions that if executed by the machine are to cause the machine to store the multi-page P/R check hint in one of a page directory base register and a hierarchical paging structure selected from a page directory table and a page directory pointer table.

23. The article of manufacture of claim 20, wherein the storage medium further stores instructions that if executed by the machine are to cause the machine to perform operations comprising grouping protected container pages in pages hierarchically below an entry in a set of hierarchical paging structures.

24. A system to process instructions comprising:
an interconnect;
a dynamic random access memory (DRAM) coupled with the interconnect, the DRAM storing instructions that if executed by the system are to cause the system to perform operations comprising providing a multi-page protected container page versus regular page (P/R) check hint; and
a processor coupled with the interconnect, the processor in conjunction with performing a page table walk to:
check for the multi-page P/R check hint;
if the multi-page P/R check hint is found, then check a P/R indication; and
if the multi-page P/R check hint is not found, then do not check the P/R indication.

25. The system of claim 24, wherein the processor is to find the multi-page P/R check hint in one of a page directory base register, a hierarchical paging structure that is to be at a hierarchical level between the page directory base register and a page table, and a state save area.
